(19) United States
(12) Patent Application Publication
(10) Pub. No.: US 2024/0369929 A1
(43) Pub. Date: Nov. 7, 2024

(54) COMPOSITION AND METHOD OF MANUFACTURING SEMICONDUCTOR DEVICE

(71) Applicant: TAIWAN SEMICONDUCTOR MANUFACTURING COMPANY, LTD., Hsinchu (TW)

(72) Inventors: Jing Hong HUANG, Kaohsiung City (TW); Wei-Han LAI, New Taipei City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/312,199

(22) Filed: May 4, 2023

(51) Int. Cl. G03F 7/11; G03F 7/09; H01L 21/027; H01L 21/8238

(52) U.S. Cl. CPC G03F 7/11; G03F 7/091; H01L 21/0276; H01L 21/823842; H01L 27/0924

(57) ABSTRACT

A method of manufacturing a semiconductor device includes the following operations. A protective layer is formed over a substrate, in which the protective layer is formed by a composition including a polymer having a polymer backbone and end groups. The polymer backbone is formed by polymerizing a monomer composition including first monomers, and each of the first monomer independently has an aryl substituted with 1, 2, 3, 4, or 5 hydroxyl groups. The end groups include:

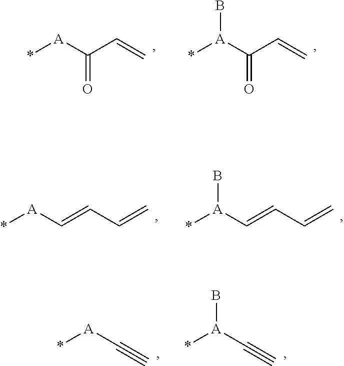

or combinations thereof. A is a substituted or unsubstituted hydrocarbon group. B is a hydroxyl group, an alkyl group, or a fluoroalkyl group. A photoresist layer is formed over the protective layer. The photoresist layer is patterned.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that was not exposed, can be exploited to remove one region without removing the other.

However, as the size of individual devices has decreased, process windows for photolithographic processing has become tighter and tighter. As such, advances in the field of photolithographic processing are preferred to maintain the ability to scale down the devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows polymers used for a protective layer in accordance with some embodiments.

FIGS. 2-5 show schematic diagrams of crosslinking polymers and cross-linkers in accordance with some embodiments.

FIG. 6 shows an additive used for a protective layer in accordance with some embodiments.

FIG. 7 is a top view of a semiconductor device in accordance with some embodiments.

FIG. 8 is a cross-sectional view along a line A-A of FIG. 7 in accordance with some embodiments.

FIGS. 9-18 are cross-sectional views of the semiconductor device during manufacturing in accordance with some embodiments.

FIG. 19 is a cross-sectional view along a line B-B of FIG. 18 in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

The formation of integrated circuits may include multiple etching processes, in which etching masks are used to define the patterns of etching. An etching mask may be a bi-layer mask, which includes a bottom layer (e.g., anti-reflective coating (BARC)) and a photoresist layer over the bottom layer, or a tri-layer mask, which includes a bottom layer, a middle layer over the bottom layer, and a photoresist layer over the middle layer.

An etching mask may be used for patterning a metal-containing layer. For example, in order to reduce gate leakage and enhance device performance, the formation of a metal gate includes removing a dummy polysilicon gate, depositing a work function metal layer, forming an etching mask over the work function metal layer, and patterning the work function metal layer by, for example, wet etching. The work function metal layer may substantially conformally cover a substrate having a plurality of protrusions (e.g., fin) and a plurality of gaps. When forming an etching mask over the work function metal layer, a bottom layer (e.g., BARC) of the etching mask should fill into the gaps to protect the work function metal layer. However, the gap-filling ability of the bottom layer is decreasing in small gaps (with gap widths less than or equal to 10 nm). If the bottom layer does not have high gap-filling ability, high wet etch resistance, and good adhesion ability to the metal layer, a portion of the work function metal layer may not be protected by the bottom layer, thereby resulting in damage or defect of the work function metal layer during the wet etching. The bottom layer is formed by crosslinking polymers. The gap-filling ability and the wet etch resistance are influenced by the molecular weight of the polymers. For a gap having a gap width less than or equal to about 10 nm, if the polymers have a low molecular weight (e.g., 100-4000), the bottom layer can have high gap-filling ability but low wet etch resistance because of the bottom layer includes small grains formed by the polymers. In contrast, if the polymers have a high molecular weight (e.g., >4000), the bottom layer can have high wet etch resistance but low gap-filling ability because of the bottom layer includes large grains formed by the polymers. Therefore, the design of the polymers used for forming the bottom layer should overcome these problems and should be proper for the bottom layer.

The present disclosure provides a composition for forming a protective layer that can be used as a bottom layer (e.g., BARC) of an etching mask and a method of manufacturing a semiconductor device by using the protective layer. The protective layer has high gap-filling ability, high wet etch resistance, and good adhesion ability to a metal-containing layer, such as a work function metal layer.

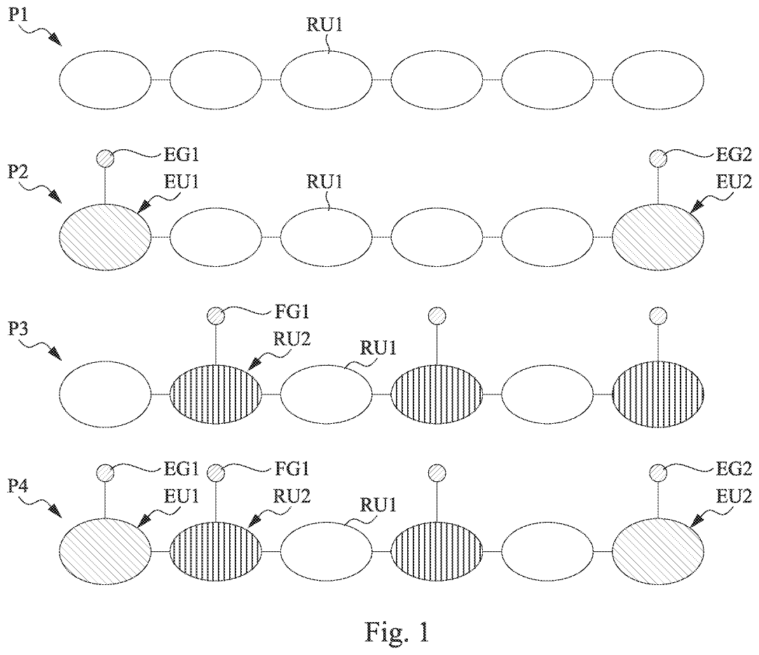

The composition of the present disclosure includes one or more cross-linkable polymers. FIG. 1 shows polymers used for a protective layer in accordance with some embodiments. As shown in FIG. 1, a polymer P1 includes repeating units RU1. A polymer P2 includes repeating units RU1, an end unit EU1, and an end unit EU2. The end unit EU1 has an end group EG1, and the end unit EU2 has an end group EG2. The polymer P2 includes a polymer backbone (or polymer chain) and the end groups EG1, EG2 bonded with the polymer backbone. A polymer P3 includes repeating units RU1 and repeating units RU2. The repeating units RU2 have functional groups FG1. The polymer P3 includes a polymer backbone substituted with one or more functional groups FG1. A polymer P4 includes repeating units RU1, repeating units RU2, an end unit EU1, and an end unit EU2. The end unit EU1 has an end group EG1, and the end unit EU2 has an end group EG2. The polymer P4 includes a polymer backbone and the end groups EG1, EG2 bonded with the polymer backbone. The polymer P4 includes a polymer backbone substituted with one or more functional groups FG1. The unit also can be referred to as a monomer unit. The polymer P3 and the polymer P4 are random copolymers, and the arrangement of the repeating units RU1 and the repeating units RU2 shown in FIG. 1 is for illustrative purposes only and does not limit the present disclosure. In some embodiments, the polymer P3 and the polymer P4 respectively include 20 mol %-95 mol % of the repeating units RU1 and 5 mol %-80 mol % of the repeating units RU2.

It is noted that the end unit EU1 has the end group EG1, the end group EG2 has the end group EG2, and each of the repeating units RU2 has a functional group FG1. The end groups EG1, EG2 and the functional group FG1 respectively include a cross-linkable group, such as an alkenyl or an alkynyl, which can enhance the degree of cross-linking between polymers. The structures of the end groups EG1, EG2 and the functional group FG1 will be further described later. In some embodiments, the polymers P1, P2, P3, and P4 respectively include the repeating units RU1 having different structures. In some embodiments, the polymers P3 and P4 respectively include the repeating units RU2 having different structures.

In some embodiments, the polymer backbones of the polymers P1, P2, P3, and P4 independently formed by polymerizing a monomer composition including monomers independently have an aryl (e.g., benzene ring) substituted with 1, 2, 3, 4, or 5 hydroxyl groups. In some embodiments, the monomers independently have a hydroxyphenyl, a di-hydroxyphenyl, a tri-hydroxyphenyl, a tetra-hydroxyphenyl, or a penta-hydroxyphenyl. In some embodiments, the monomers independently have a cross-linkable group, such as an alkenyl. In some embodiments, the polymers P1, P2, P3, and P4 are independently a novolac polymer, a substituted poly(hydroxystyrene) (PHS), an unsubstituted poly(hydroxystyrene), an acrylate polymer, or a substituted polyethylene, and the substituted poly(hydroxystyrene) and the substituted polyethylene are respectively substituted with one or more functional groups, such as a hydroxyphenyl, a di-hydroxyphenyl, a tri-hydroxyphenyl, a tetra-hydroxyphenyl, a penta-hydroxyphenyl, or combinations thereof. For example, the functional groups include

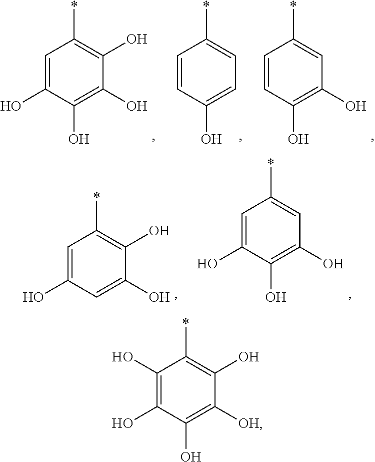

or combinations thereof.

In some embodiments, the repeating units RU1 are formed by monomers used for forming a novolac polymer, a substituted poly(hydroxystyrene), an unsubstituted poly(hydroxystyrene), an acrylate polymer, a substituted polyethylene, or combinations thereof. The substituted poly(hydroxystyrene) and the substituted polyethylene are respectively substituted with a hydroxyphenyl, a di-hydroxyphenyl, a tri-hydroxyphenyl, a tetra-hydroxyphenyl, a penta-hydroxyphenyl, or combinations thereof. In some embodiments, the monomers used for forming the repeating units RU1 includes, but not limited to,

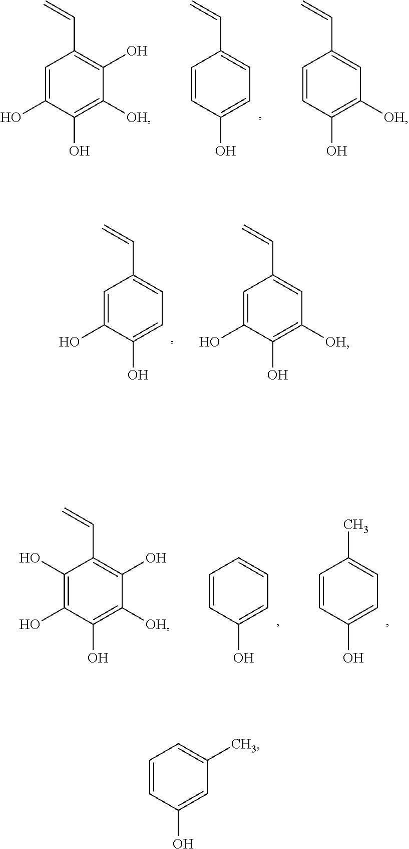

benzene-1,2-diol, benzene-1,3-diol, benzene-1,4-diol, benzene-1,2,3-triol, benzene-1,2,4-triol, benzene-1,3,5-triol, 1,2,3,4-tetrahydroxybenzene, 1,2,3,5-tetrahydroxybenzene, 1,2,4,5-tetrahydroxybenzene,

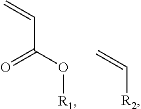

or combinations thereof. R₁ and R₂ are independently a hydroxyphenyl, a di-hydroxyphenyl, a tri-hydroxyphenyl, a tetra-hydroxyphenyl, or a penta-hydroxyphenyl. In some embodiments, a novolac polymer can be prepared by the condensation of formaldehyde and the above monomers used for forming the novolac polymer, such as phenol, m-cresol, or p-cresol. In some embodiments, the polymer backbone of polymers P1, P2, P3, or P4 has the repeating units RU1 including

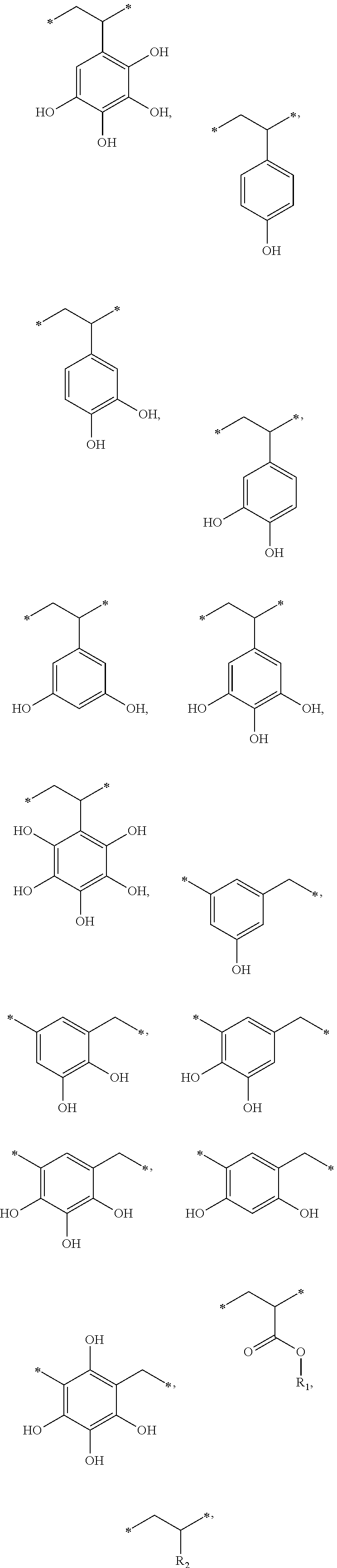

or combinations thereof. R₁ and R₂ are independently a hydroxyphenyl, a di-hydroxyphenyl, a tri-hydroxyphenyl, a tetra-hydroxyphenyl, or a penta-hydroxyphenyl. In the present disclosure, * represent a bonding position.

Still referring to FIG. 1, the end unit EU1 has the end group EG1, the end unit EU2 has the end group EG2, and the repeating units RU2 has the functional group FG1.

The end groups EG1 and EG2 or the functional groups FG1 include

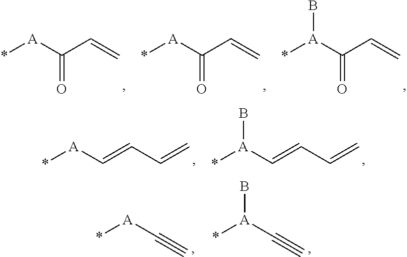

or combinations thereof. A is a substituted or unsubstituted hydrocarbon group, and B is a hydroxyl group, an alkyl group, or a fluoroalkyl group. In some embodiments, the end groups EG1 and EG2 and the functional group FG1 are the same or different from each other. In some embodiments, the polymer P3 or the polymer P4 includes different functional groups FG1. The end group EG1, the end group EG2, and the functional group FG1 respectively include an alkenyl or an alkynyl, which can enhance the degree of cross-linking between polymers. The alkynyl may have reactivity greater than that of the alkenyl. In some embodiments, A is the substituted hydrocarbon group substituted with a hydroxyl group, an ester group, a halogen group, or combinations thereof. In some embodiments, A is a branched or unbranched, cyclic or non-cyclic, or saturated or unsaturated hydrocarbon group. In some embodiments, A is a saturated hydrocarbon group, an aromatic hydrocarbon group (e.g., benzene ring), or an aromatic hydrocarbon group (e.g., benzene ring) substituted with 1, 2, 3, or 4 hydroxyl groups. In some embodiments, A has a carbon number between 1-6, such as 1, 2, 3, 4, 5, or 6. In some embodiments, the saturated hydrocarbon group has a carbon number between 1-6, such as 1, 2, 3, 4, 5, or 6. Furthermore, when A includes an aromatic hydrocarbon group (e.g., benzene ring), the reactivity of the alkenyl and the alkynyl can be enhanced. In some embodiments, B is an alkyl group having a carbon number between 1-6, such as 1, 2, 3, 4, 5, or 6. In some embodiments, B is a fluoroalkyl group having a structure of —(CH₂)ₙCFₓ, n is 1-4, and x is 1-2.

In some embodiments, the end unit EU1 or the end unit EU2 is formed by a monomer having an aryl substituted with 1, 2, 3, 4, or 5 hydroxyl groups, and the monomer is substituted with the end group EG1 or the end group EG2. In some embodiments, the monomer is used for forming a novolac polymer, a substituted poly(hydroxystyrene), an unsubstituted poly(hydroxystyrene), an acrylate polymer, a substituted polyethylene, or combinations thereof, and the monomer is substituted with the end group EG1 or the end group EG2. In some embodiments, the repeating units RU2 is formed by monomers independently having an aryl substituted with 1, 2, 3, 4, or 5 hydroxyl groups, and the monomers respectively substituted with the functional group FG1. In some embodiments, the monomers are used for forming a novolac polymer, a substituted poly(hydroxystyrene), an unsubstituted poly(hydroxystyrene), an acrylate polymer, a substituted polyethylene, or combinations thereof, and the monomers are respectively substituted with the functional group FG1.

In some embodiments, the monomers used for forming the end unit EU1, the end unit EU2, and the repeating units RU2 respectively includes, but not limited to,

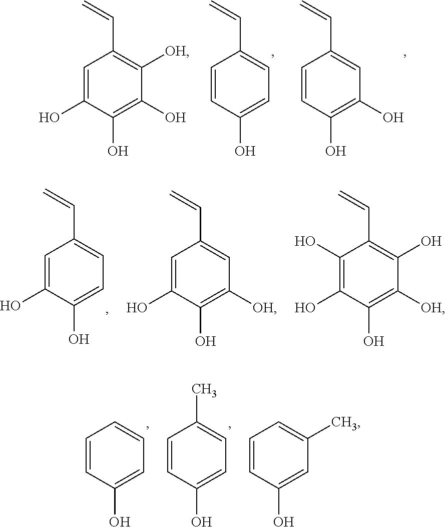

benzene-1,2-diol, benzene-1,3-diol, benzene-1,4-diol, benzene-1,2,3-triol, benzene-1,2,4-triol, benzene-1,3,5-triol, 1,2,3,4-tetrahydroxybenzene, 1,2,3,5-tetrahydroxybenzene, 1,2,4,5-tetrahydroxybenzene,

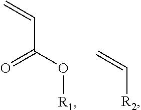

or combinations thereof, and the monomers are substituted with one or more functional groups, such as the end group EG1, the end group EG2, or the functional group FG1. R₁ and R₂ are independently a hydroxyphenyl, a di-hydroxyphenyl, a tri-hydroxyphenyl, a tetra-hydroxyphenyl, or a penta-hydroxyphenyl. In some embodiments, the end unit EU1, the end unit EU2, and the repeating units RU2 respectively include

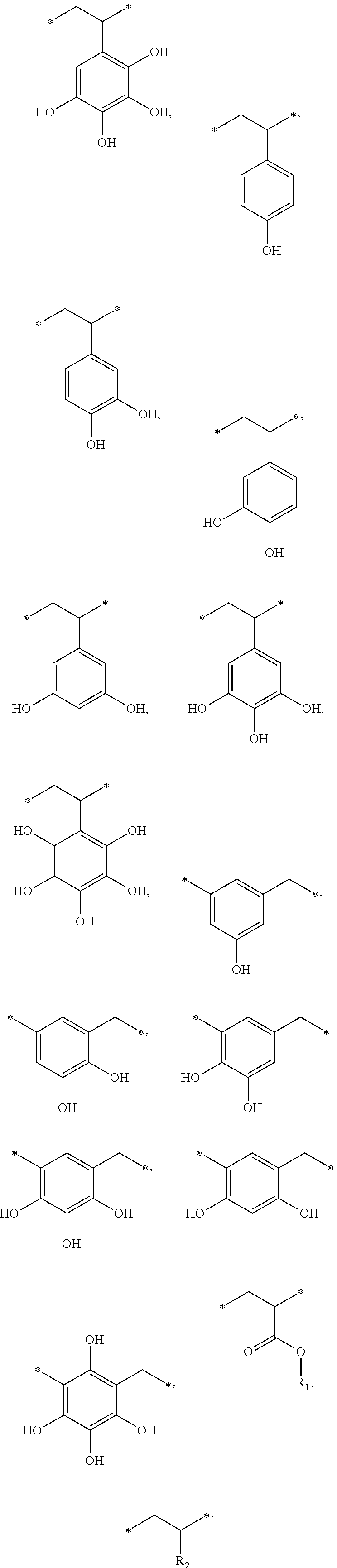

or combinations thereof. R₁ and R₂ are independently a hydroxyphenyl, a di-hydroxyphenyl, a tri-hydroxyphenyl, a tetra-hydroxyphenyl, or a penta-hydroxyphenyl, and the end unit EU1, the end unit EU2, and the repeating units RU2 are substituted with one or more functional groups, such as the end group EG1, the end group EG2, or the functional group FG1.

In some embodiments,

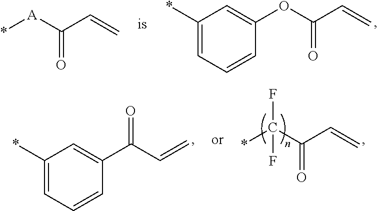

and n is 1-2.

In some embodiments.

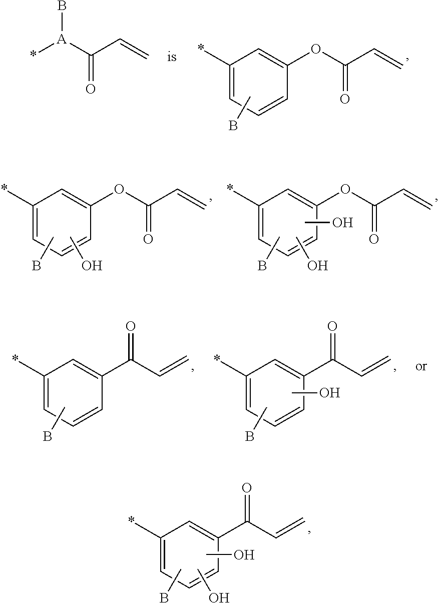

such as

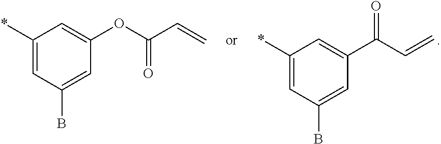

In some embodiments,

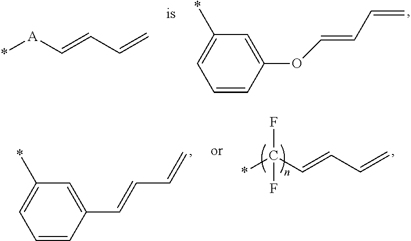

and n is 1-2.

In some embodiments.

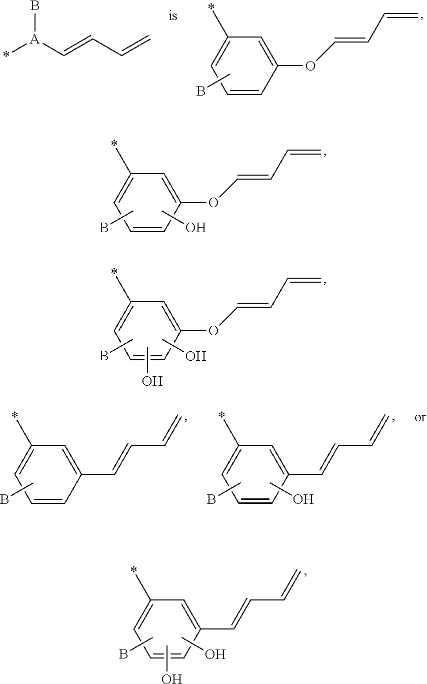

such as

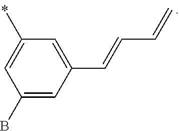

In some embodiments.

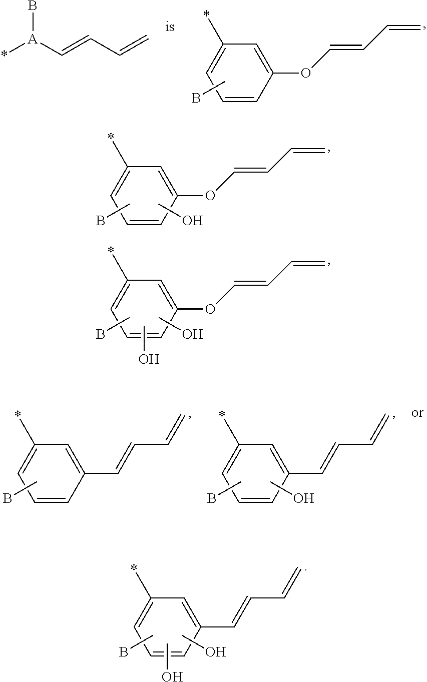

In some embodiments.

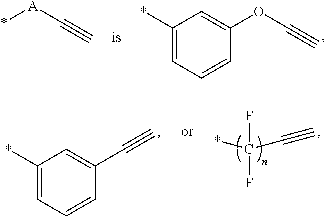

and n is 1-2.

In some embodiments,

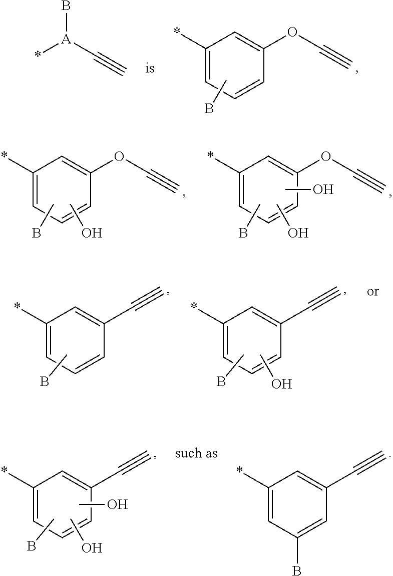

Still referring to FIG. 1, in some embodiments, a composition used for forming a protective layer includes the polymer P2, the polymer P3, the polymer P4, or combinations thereof. More specifically, the composition can include the polymer P2, the polymer P3, the polymer P4, the polymers P2 and P3, the polymers P2 and P4, the polymers P3 and P4, or the polymers P2, P3, and P4. In some embodiments, the composition further includes the polymer P1. In some embodiments, the polymer P1, polymer P2, the polymer P3, and the polymer P4 respectively have a weight-average molecular weight between greater than 1000 daltons and 10000 daltons, such as 1100, 1500, 2000, 3000, 4000, 5000, 6000, 7000, 8000, 9000, or 10000 daltons.

In some embodiments, a composition used for forming a protective layer includes a polymer has a polymer backbone and end units, in which the polymer backbone and the end units are independently unsubstituted or substituted with one or more functional groups including

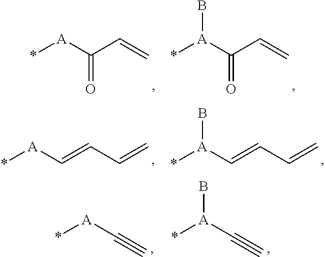

or combinations thereof. A is a substituted or unsubstituted hydrocarbon group. B is a hydroxyl group, an alkyl group, or a fluoroalkyl group. The polymer backbone, the end units, or a combination thereof is substituted. If the polymer backbone is substituted, the polymer is the polymer P3. If the end units are substituted, the polymer is the polymer P2. If the polymer backbone and the end units are substituted, the polymer is the polymer P4.

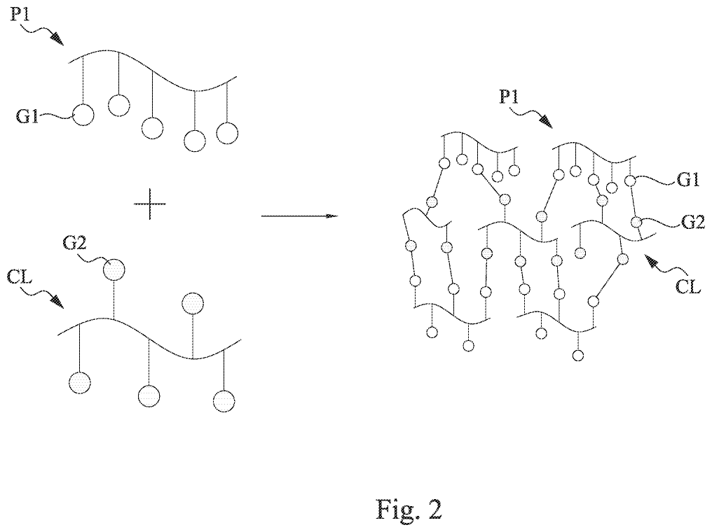

In some embodiments, the composition includes one or more polymers used for forming a protective layer, a cross-linker, and a solvent. In some other embodiments, the composition includes one or more polymers used for forming a protective layer and a solvent, and the composition is free of a cross-linker because of the polymer has cross-linkable groups, such as the end group EG1, the end group EG2, the functional group FG1, or combinations thereof. In some embodiments, the composition further includes an initiator. In some embodiments, a bake process can be performed to induce the cross-linking reaction and enhance the degree of cross-linking of the components in the composition. In other words, the bake process can promote the crosslinking reactions shown in FIGS. 2-5. In some embodiments, the baking temperature is between 180° C. and 300° C., such as 180, 200, 220, 240, 260, 280, or 300° C. If the baking temperature is greater than 300° C., the polymers may degrade. In some embodiments, the composition further includes a surfactant.

In some embodiments, the cross-linker has one or more epoxy group. In some embodiments, the cross-linker can be formed by monomers used for forming a novolac polymer, a substituted poly(hydroxystyrene), an unsubstituted poly(hydroxystyrene), an acrylate polymer, a substituted polyethylene, or combinations thereof, and the cross-linker is substituted with one or more epoxy group, which can react with the hydroxyl groups in the polymer. Please refer to the embodiments of the polymer P1 for the structure and the forming method of the cross-linker. The difference between the cross-linker and the polymer P1 is that the cross-linker is substituted with one or more epoxy group. In some embodiments, the cross-linker has a weight-average molecular weight between 100 daltons and 10000 daltons, such as 100, 500, 1000, 2000, 3000, 4000, 5000, 6000, 7000, 8000, 9000, or 10000 daltons.

In some embodiments, the solvent includes propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, 4-methyl-2-pentanol, acetone, methyl ethyl ketone, dimethylformamide (DMF), isopropanol (IPA), tetrahydrofuran (THF), methyl isobutyl carbinol (MIBC), n-butyl acetate (nBA), 2-heptanone (MAK), dioxane, or combinations thereof. In some embodiments, the initiator is a thermal radical initiator, a photo radical initiator, or a combination thereof. In some embodiments, the thermal radical initiator is one or more selected from the group consisting of azobisisobutyronitrile (AIBN), 2,2′-azodi (2-methylbutyronitrile) (AMBN), 2,2′-azobis(2,4-dimethyl) valeronitrile (ADVN), 4,4′-azobis(4-cyanopentanoic acid) (ACVA), dimethyl 2,2′-azobis(2-methylpropionate), 2,2′-azobis(2-amidinopropane) dihydrochloride (AAPH), 2,2′-azobis [2-(2-imidazolin-2-yl)-propane] dihydrochloride, tert-butyl-hydroperoxide (TBHP), cumene hydroperoxide, di-tert-butyl peroxide, dicumyl peroxide, benzoyl peroxide (BPO), dicyandiamide, cyclohexyl tosylate, diphenyl(methyl) sulfonium tetrafluoroborate, benzyl (4-hydroxyphenyl)-methylsulfonium hexafluoroantimonate, and (4-hydroxyphenyl) methyl-(2-methylbenzyl) sulfonium hexafluoroantimonate. In some embodiments, the photo radical initiator is one or more selected from the group consisting of camphorquinone, acetophenone, 3-acetophenol, 4-acetophenol, benzophenone, 2-methylbenzophenone, 3-methylbenzophenone. 3-hydroxybenzophenone, 3,4-dimethylbenzophenone, 4-hydroxybenzophenone, 4-benzoylbenzoic acid, 2-benzoylbenzoic acid, methyl 2-benzoylbenzoate, 4,4′-dihydroxybenzophenone, 4-(dimethylamino)-benzophenone, 4,4′-bis(dimethylamino)-benzophenone, 4,4′-bis(diethylamino)-benzophenone, 4,4′-dichlorobenzophenone, 4-(p-tolylthio) benzophenone, 4-phenylbenzophenone, 1,4-dibenzoylbenzene, benzil, 4,4′-dimethylbenzil, p-anisil, 2-benzoyl-2-propanol, 2-hydroxy-4′-(2-hydroxyethoxy)-2-methylpropiophenone, 1-benzoylcyclohexanol, benzoin, and anisoin.

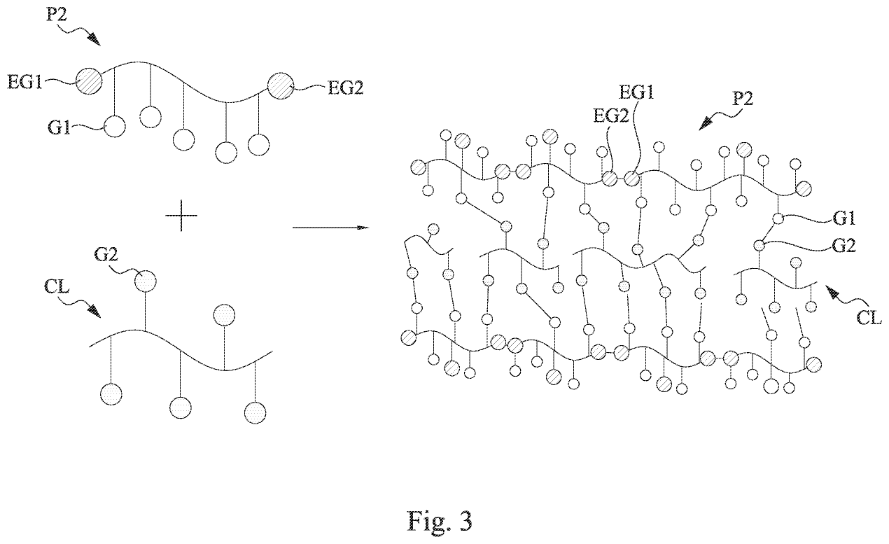

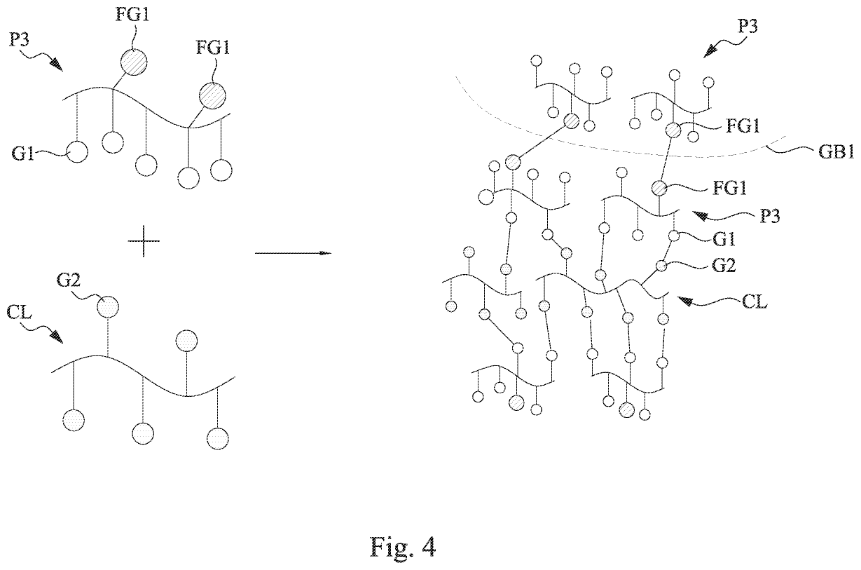

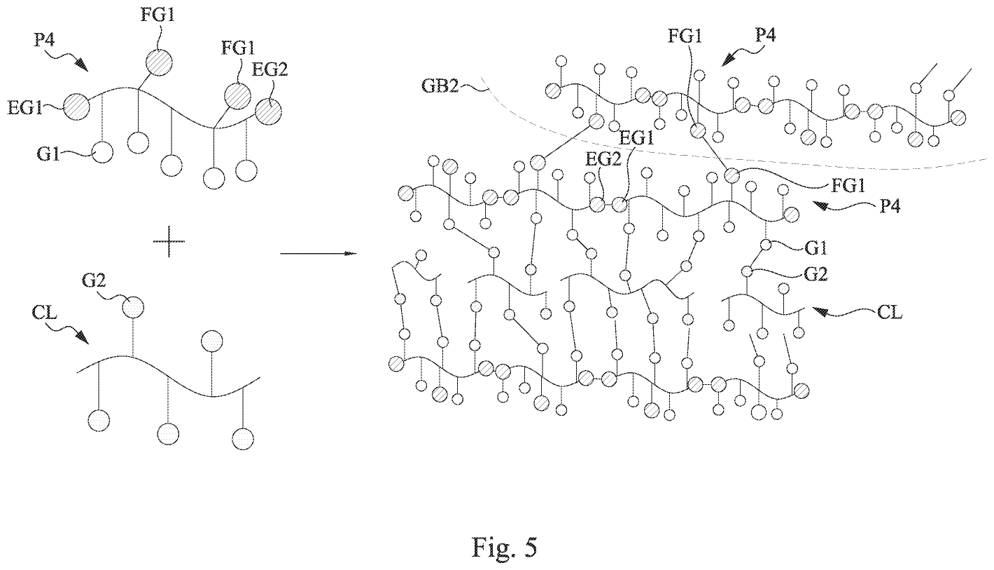

Please refer to FIGS. 1-5. FIGS. 2-5 show schematic diagrams of crosslinking polymers and cross-linkers in accordance with some embodiments. As shown in FIG. 2, the polymers P1 and the cross-linkers CL are cross-linked with each other by reacting the groups G1 (e.g., hydroxyl group) of the polymers P1 with the groups G2 (e.g., epoxy group) of the cross-linkers CL. As shown in FIG. 3, the polymers P2 and the cross-linkers CL are cross-linked with each other by reacting the groups G1 (e.g., hydroxyl group) of the polymers P2 with the groups G2 (e.g., epoxy group) of the cross-linkers CL. Moreover, the polymers P2 also can be bonded with each other by reacting the end groups EG1 and EG2 (including an alkenyl, an alkynyl, or a combination) of the polymers P2. Therefore, the polymers P2 and the cross-linkers CL can form grains greater than grains formed by the polymers P1 and the cross-linkers CL. Furthermore, the bonds formed by the groups G1 and G2 may be —C—O—C—, and the bond cleavage may easily occur in the presence of a wet etchant. The bonds formed by the end groups EG1 and EG2 may be —C—C— or —C═C—, which has a wet etch resistance higher than that of —C—O—C—. Therefore, the polymers P2 has a wet etch resistance better than that of the polymers P1 due to the larger grains, —C—C—, and/or —C═C—. As shown in FIG. 4, the polymers P3 and the cross-linkers CL are cross-linked with each other by reacting the groups G1 (e.g., hydroxyl group) of the polymers P3 with the groups G2 (e.g., epoxy group) of the cross-linkers CL. Moreover, the polymers P3 can be bonded with each other by reacting the functional groups FG1 (including an alkenyl, an alkynyl, or a combination) of the polymers P3. In other words, the grains formed by the polymers P3 and the cross-linkers CL can further be bonded with each other by reacting the functional groups FG1. FIG. 4 shows a grain boundary GB1. Therefore, the polymers P3 and the cross-linkers CL can form grains greater than grains formed by the polymers P1 and the cross-linkers CL. Furthermore, the bonds formed by the groups G1 and G2 may be —C—O—C—, and the bonds formed by the functional groups FG1 may be —C—C— or —C—C—, which has a wet etch resistance higher than that of —C—O—C—. Therefore, the polymers P3 has a wet etch resistance better than that of the polymers P1 due to the larger grains, —C—C—, and/or —C═C—. As shown in FIG. 5, the polymers P4 and the cross-linkers CL are cross-linked with each other by reacting the groups G1 (e.g., hydroxyl group) of the polymers P4 with the groups G2 (e.g., epoxy group) of the cross-linkers CL. Moreover, the polymers P4 also can be bonded with each other by reacting the end groups EG1 and EG2 (including an alkenyl, an alkynyl, or a combination) of the polymers P4. Furthermore, the polymers P4 also can be bonded with each other by reacting the functional groups FG1 (including an alkenyl, an alkynyl, or a combination) of the polymers P4. In other words, the grains formed by the polymers P4 and the cross-linkers CL can further be bonded with each other by reacting the functional groups FG1. FIG. 5 shows a grain boundary GB2. The polymers P4 has a wet etch resistance better than that of the polymers P1, the polymers P2, or the polymers P3 due to the larger grains, —C—C—, and/or —C═C—.

In some embodiments, the composition used for forming the protective layer further includes an oligomer to enhance the gap-filling ability of the composition. The oligomer is easier to flow into small gaps due to the smaller volume. Subsequently, the oligomer can be crosslinked with the polymer. The oligomer has an oligomer backbone and end units and has a weight-average molecular weight between 500 daltons and 1000 daltons, such as 500, 600, 700, 800, 900, or 1000 daltons. Please refer to the embodiments of the polymers for the structure and the forming method of the oligomer. The difference between the oligomer and the polymer is the weight-average molecular weight. For example, the oligomer backbone and the end units are independently unsubstituted or substituted with one or more functional groups including

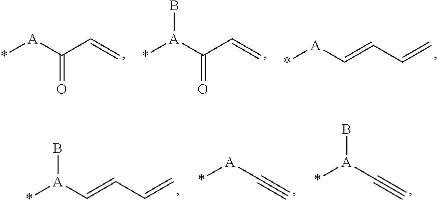

or combinations thereof. The oligomer backbone, the end units, or a combination thereof is substituted. Please refer to the previously mentioned embodiments for the embodiments of A and B, and detailed descriptions thereof will not be repeated here.

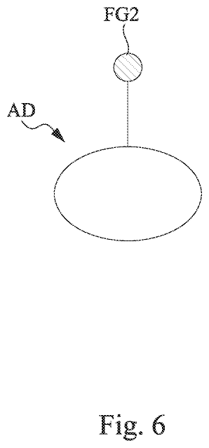

In some embodiments, the composition used for forming the protective layer further includes one or more additives to enhance the gap-filling ability of the composition. The additive is easier to flow into small gaps due to the smaller volume. Subsequently, the oligomer can be crosslinked with the polymer and/or the oligomer. FIG. 6 shows an additive AD having a functional group FG2 used for a protective layer in accordance with some embodiments. Please refer to the embodiments of the functional group FG1 for the embodiments of the functional group FG2. In other words, the functional group FG2 is the same as the functional group FG1. Please refer to the embodiments of the monomers used for forming the repeating units RU2 for the embodiments of the monomers used for forming the additive AD. In some embodiments, the additives include monomers independently has an aryl (e.g., benzene ring) substituted with 1, 2, 3, 4, or 5 hydroxyl groups, and the monomers are substituted with the functional group FG2. In some embodiments, the additives are monomers used for forming a novolac polymer, a substituted poly(hydroxystyrene), an unsubstituted poly(hydroxystyrene), an acrylate polymer, a substituted polyethylene, or combinations thereof. The substituted poly(hydroxystyrene) and the substituted polyethylene are respectively substituted with a hydroxyphenyl, a di-hydroxyphenyl, a tri-hydroxyphenyl, a tetra-hydroxyphenyl, a penta-hydroxyphenyl, or combinations thereof, and the monomers are substituted with the functional group FG2. In some embodiments, the additive has a weight-average molecular weight between 50 daltons and less than 500 daltons, such as 50, 100, 200, 300, 400, 450 daltons.

In some embodiments, the composition includes additives having different structures. In some embodiments, the composition include one or more additives including:

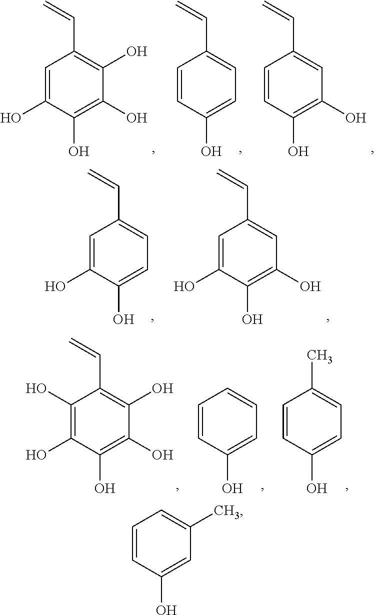

benzene-1,2-diol, benzene-1,3-diol, benzene-1,4-diol, benzene-1,2,3-triol, benzene-1,2,4-triol, benzene-1,3,5-triol, 1,2,3,4-tetrahydroxybenzene, 1,2,3,5-tetrahydroxybenzene, 1,2,4,5-tetrahydroxybenzene,

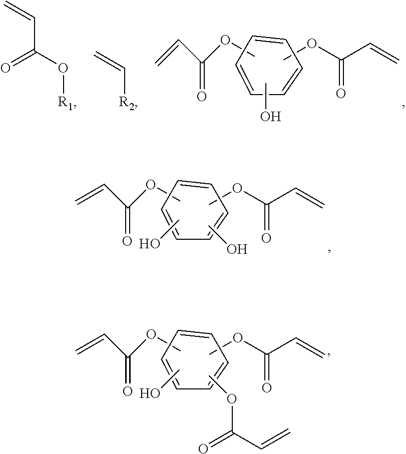

or combinations thereof, R₁ and R₂ are independently a hydroxyphenyl, a di-hydroxyphenyl, a tri-hydroxyphenyl, a tetra-hydroxyphenyl, or a penta-hydroxyphenyl, and the additives are respectively substituted with one or more functional groups including:

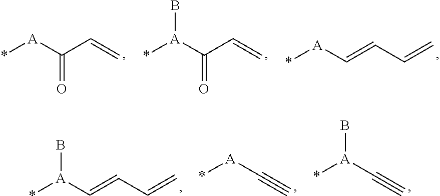

or combinations thereof. A is a substituted or unsubstituted hydrocarbon group, and B is a hydroxyl group, an alkyl group, or a fluoroalkyl group. Please refer to the previously mentioned embodiments for the embodiments of A and B, and detailed descriptions thereof will not be repeated here.

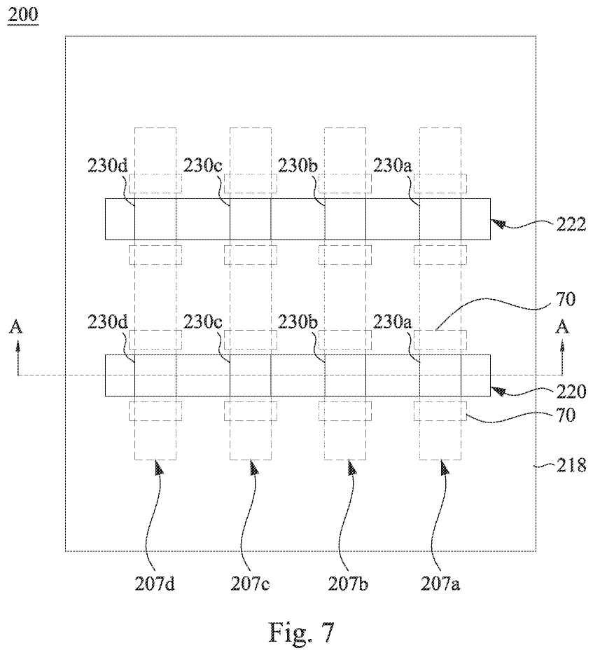

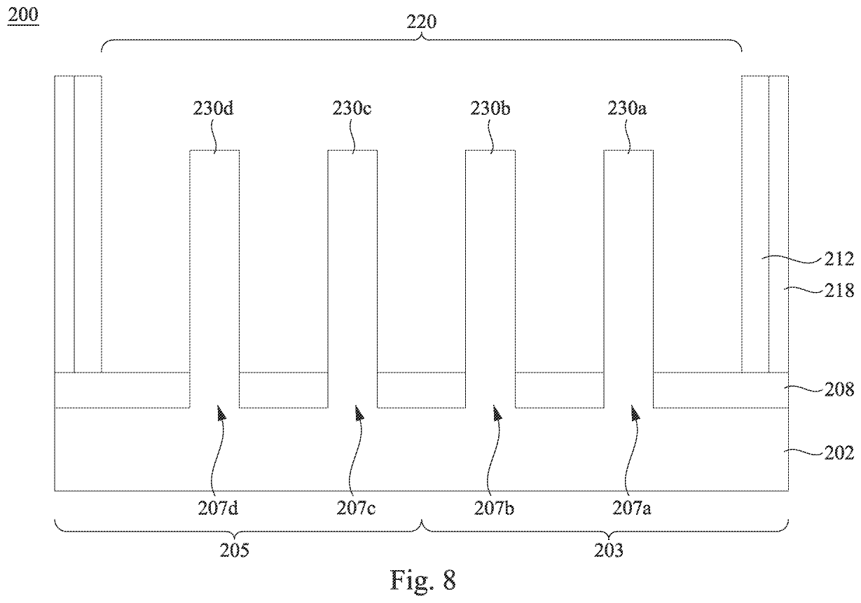

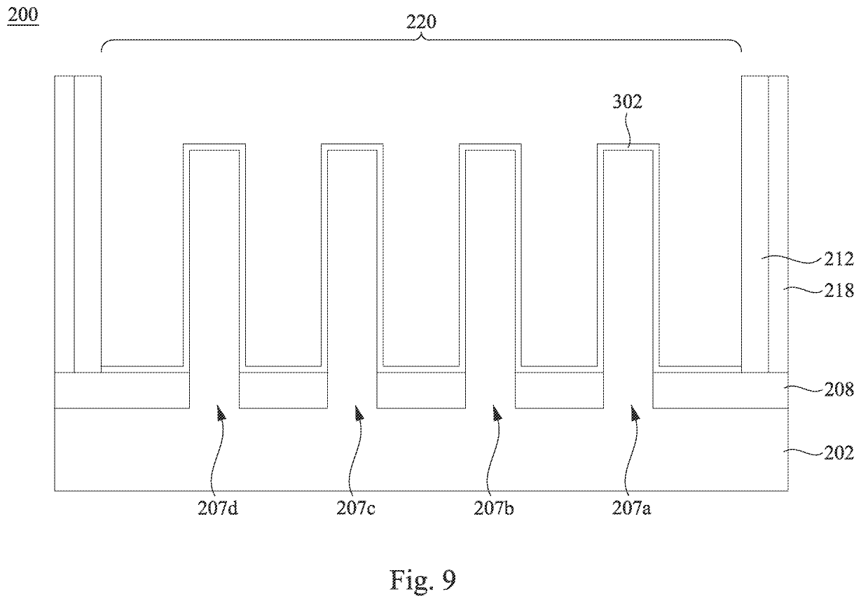

Next, the present disclosure provides a method of manufacturing a semiconductor device. FIG. 7 is a top view of a semiconductor device in accordance with some embodiments. FIG. 8 is a cross-sectional view along a line A-A of FIG. 7 in accordance with some embodiments. FIGS. 9-18 are cross-sectional views of the semiconductor device during manufacturing in accordance with some embodiments.

During fabrication of a fin field effect transistor (FinFET) device, a gate replacement process may be implemented to adjust threshold voltage (Vt) associated with the fabrication steps. For example, during a “gate-last” process, a dummy gate structure is first formed over a substrate as a placeholder before forming other components, e.g., source/drain features. Once the other components have been formed, the dummy gate structure is removed, and a metal gate structure is formed in its place. Multiple patterning processes may be implemented to form various material layers within the metal gate structure to provide certain device capabilities such as multiple threshold voltages. Multi-threshold voltage (Vt) devices enable flexible and diverse applications of field effect transistors (FETs).

Multiple threshold voltages of the FinFET device have been accomplished by stacking multiple work function metal (WFM) layers in the metal gate structure. In one example, a thicker WFM stack leads to a higher work function and a higher threshold voltage (Vt). However, as device feature sizes decrease, many challenges arise when stacking WFM layers. For example, because of decreased fin-to-fin pitches, when forming an etching mask over the work function metal layer, the etching mask may not easily fill into the gaps between fins to protect the work function metal layer.

As shown in FIGS. 7-8, the semiconductor device 200 may be an intermediate device (or an IC structure) fabricated during processing of an IC that may comprise static random-access memory (SRAM) and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells The present disclosure is not limited to any particular number of devices or device regions, or to any particular device configurations. For example, although the semiconductor device 200 as illustrated is a three-dimensional FinFET device, the present disclosure may also provide embodiments for fabricating planar FET devices.

The semiconductor device 200 is provided and includes a substrate 202 having a first region 203 and a second region 205, isolation structures 208 formed over the substrate 202 separating various components of the semiconductor device 200, gate spacers 212 as well as an interlayer dielectric (ILD) layer 218 formed on the isolation structures 208. In some embodiments, the first region 203 includes two fins, a fin 207a and a fin 207b, and the second region 205 also includes two fins, a fin 207c and a fin 207d. The fins 207a-207d may include FET features, such as channel regions 230a, 230b, 230c, and 230d, respectively. As shown in FIG. 7, source/drain regions 70 are formed on each of fins 207a-207d and are separated by the channel regions 230a-230d. As shown in FIG. 8, fins 207a-207d are aligned from right to left, but the present disclosure works with any order of the fins 207a-207d, which may or may not be immediately adjacent to each other.

Still referring to FIGS. 7-8, gate trenches 220 and 222 are formed to expose the channel regions 230a-230d of the fins 207a-207d. As shown in FIG. 8, the gate spacers 212 and the ILD layer 218 define two gate trenches 220 and 222, which are to be filled by metallic materials. From the top view of FIG. 7, the fins 207a-207d are generally covered by the ILD layer 218, but the gate trenches 220 and 222 each expose a respective set of channel regions 230a-230d. For purpose of simplicity, the operations of the method are illustrated with respect to the gate trench 220 (but not gate trench 222 as it undergoes the same fabrication processes).

In some embodiments, the gate trench 220 is formed by removing a dummy gate structure on the fins 207a-207d, thereby exposing the channel regions 230a-230d of the fins 207a-207d. The dummy gate structure may include one or more material layers, such as an oxide layer (i.e., a dummy gate dielectric layer), a poly-silicon layer (i.e., a dummy gate electrode), a hard mask layer, a capping layer, and/or other suitable layers. In some embodiments, forming the gate trench 220 includes performing an etch process that selectively removes the dummy gate structure using a dry etch process, a wet etch process, other suitable methods, or combinations thereof. A dry etch process may use chlorine-containing gases, fluorine-containing gases, and/or other etching gases. The wet etching solutions may include ammonium hydroxide (NH₄OH), hydrofluoric acid (HF) or diluted HF, deionized water, tetramethylammonium hydroxide (TMAH), and/or other suitable wet etching solutions.

As shown in FIGS. 7-8, the substrate 202 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 202 may be a single-layer material having a uniform composition. Alternatively, the substrate 202 may include multiple material layers having similar or different compositions suitable for IC device manufacturing. In some embodiments, the substrate 202 may be a silicon-on-insulator (SOI) substrate having a silicon layer formed on a silicon oxide layer. In some other embodiments, the substrate 202 may include a conductive layer, a semiconductor layer, a dielectric layer, other layers, or combinations thereof.

In some embodiments, the substrate 202 includes FETs, various doped regions, such as source/drain regions, formed in or on the substrate 202. The doped regions may be doped with p-type dopants, such as phosphorus or arsenic, and/or n-type dopants, such as boron or BF₂, depending on design specifications. The doped regions may be formed directly on the substrate 202, in a p-well structure, in an n-well structure, in a dual-well structure, or using a raised structure. Doped regions may be formed by implantation of dopant atoms, in-situ doped epitaxial growth, and/or other suitable techniques.

The first region 203 may be suitable for forming one or more n-type FinFETs, and the second region 205 may be suitable for forming one or more p-type FinFETs. Therefore, the channel regions 230a and 230b located on the fins 207a and 207b are n-type channels, and the channel regions 230c and 230d located on the fins 207c and 207d are p-type channels. In alternative embodiments, the first region 203 and the second region 205 may be suitable for forming FinFETs of a similar type, i.e., both n-type or both p-type, with different threshold voltage (Vt) design specifications. This configuration in FIGS. 7-8 is for illustrative purposes only and does not limit the present disclosure. The fins 207a-207d may be fabricated using suitable processes including photolithography and etch processes. The photolithography process may include forming a photoresist layer (resist) overlying the substrate 202, exposing the resist to a pattern, performing post-exposure bake processes, and developing the resist to form a masking element (not shown) including the resist. The masking element is then used for etching recesses into the substrate 202, leaving the fins 207a-207d on the substrate 202. The etch process may include dry etching, wet etching, reactive ion etching (RIE), and/or other suitable processes.

Other methods for forming the fins 207a-207d may be suitable. For example, the fins 207a-207d may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

The isolation structures 208 may include silicon oxide, silicon nitride, silicon oxynitride, fluoride-doped silicate glass (FSG), a low-k dielectric material, and/or other suitable materials. The isolation structures 208 may include shallow trench isolation (STI) features. In some embodiments, the isolation structures 208 are formed by etching trenches in the substrate 202 during the formation of the fins 207a-207c. The trenches may then be filled with an isolating material described above, followed by a chemical mechanical planarization (CMP) process. Other isolation structures such as field oxide, local oxidation of silicon (LOCOS), and/or other suitable structures may also be implemented as the isolation structures 208. Alternatively, the isolation structures 208 may include a multi-layer structure, for example, having one or more thermal oxide liner layers.

The gate spacers 212 form sidewalls of the gate trench 220. The gate spacers 212 may include a dielectric material, such as silicon oxide, silicon nitride, silicon carbide, silicon oxynitride, and/or other suitable dielectric materials. The gate spacers 212 may be a single layered structure or a multi-layered structure. In some embodiments, the ILD layer 218 includes a dielectric material, such as tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 218 may include a multi-layer structure having multiple dielectric materials.

Please refer to FIG. 9. An interfacial layer (IL) 302 is formed in the gate trench 220 over the fins 207a-207d. The interfacial layer 302 may include a dielectric material such as silicon oxide or silicon oxynitride (SiON). The interfacial layer 302 may be formed to any suitable thickness such as about 0.5 nm to about 1.5 nm. The interfacial layer 302 may be formed by any suitable deposition techniques, such as chemical oxidation, thermal oxidation, atomic layer deposition (ALD), chemical vapor deposition (CVD), physical vapor deposition (PVD), low-pressure chemical vapor deposition (LP-CVD), plasma-enhanced CVD (PE-CVD), high-density plasma CVD (HDP-CVD), metal organic CVD (MO-CVD), remote plasma CVD (RP-CVD), atomic layer CVD (AL-CVD), atmospheric pressure CVD (AP-CVD), and/or other suitable methods.

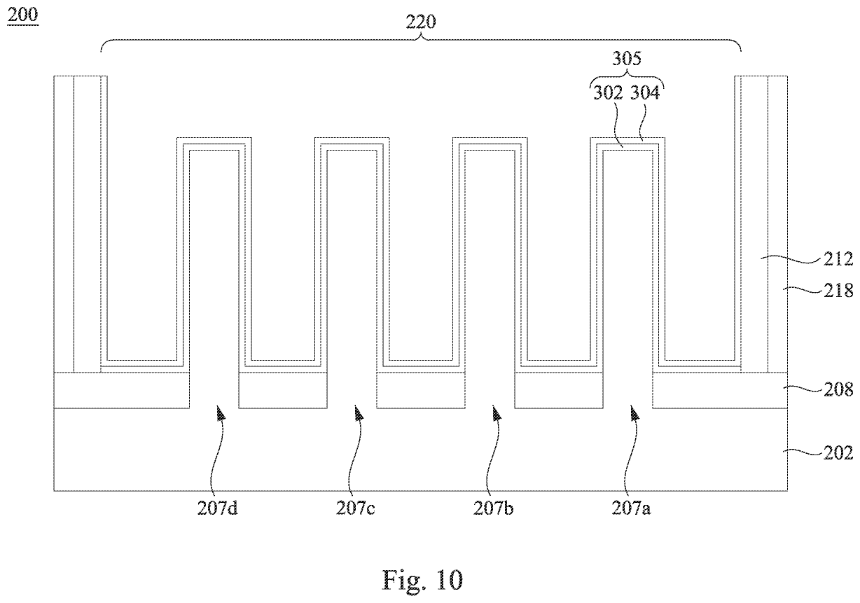

Please refer to FIG. 10. A high-k dielectric layer 304 is formed in the gate trench 220 over the interfacial layer 302. In the present disclosure, “high-k” dielectric generally refers to one or more materials having a dielectric constant greater than that of silicon dioxide (SiO₂). The high-k dielectric layer 304 may be formed by ALD and/or other suitable methods to any suitable thickness. In an embodiment, the high-k dielectric layer 304 has a thickness of about 1 nm to about 2 nm. In some other embodiments, the high-k dielectric layer 304 may be formed over an intermediate material layer such that the high-k dielectric layer 304 is not directly in contact with the interfacial layer 302. In some embodiments, the high-k dielectric layer 304 includes oxides based on hafnium, zirconium, silicon, and/or other suitable materials. For example, the high-k dielectric layer 304 may include hafnium oxide (HfO2), hafnium silicon oxide, and/or hafnium zirconium oxide, etc. Since both the high-k dielectric layer 304 and the interfacial layer 302 are dielectric layers used in the gate structure, they are collectively referred to as a gate dielectric layer 305.

Following the formation of the gate dielectric layer 305, a work function metal (WFM) layer is formed thereon to provide work functions to adjust threshold voltages for the subsequent transistors. Each fin may be used to implement a FinFET with a source, a drain, a channel, and a gate, and a threshold voltage of the fin refers to a minimum gate-to-source voltage to create a conducting path in the channel between the source and the drain. Source/drain region(s) may refer to a source or a drain, individually or collectively dependent upon the context. The threshold voltage is impacted by various parameters including the work function of the gate. As device feature sizes decrease, implementing thick WFM structures during lithography and patterning processes poses many challenges.

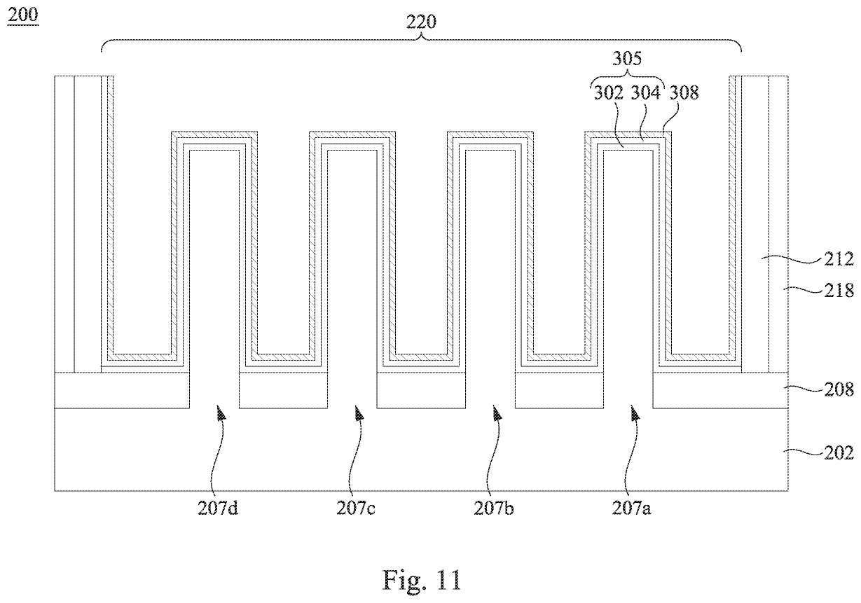

Please refer to FIG. 11. A p-type WFM layer 308 is formed over the high-k dielectric layer 304 in the gate trench 220. In some embodiments, the p-type WFM layer 308 substantially conformally covers the gate dielectric layer 305. In other words, the p-type WFM layer 308 substantially conformally covers a substrate including the substrate 202, the isolation structures 208, and the gate dielectric layer 305, and this substrate has a plurality of protrusions and a plurality of gaps as shown in FIG. 11. The p-type WFM layer 308 may include a metal with a sufficiently large effective work function, selected from but not restricted to the group of titanium nitride (TiN), tantalum nitride (TaN), ruthenium (Ru), molybdenum (Mo), tungsten (W), platinum (Pt), tungsten carbon nitride (WCN), titanium aluminum nitride (TiAIN), or combinations thereof. The p-type WFM layer 308 may be formed by a deposition process such as ALD, CVD, PVD, and/or other suitable processes. Therefore, depending on the desired work function on the fin 207c and 207d, the p-type WFM layer 308 may have any suitable thickness, such as about 1 nm to about 2 nm. In some embodiments, for patterning efficiency, the p-type WFM layer 308 is less than 1.5 nm thick. Further, as shown in FIG. 11, in some embodiments, the p-type WFM layer 308 is in direct contact with the high-k dielectric layer 304 without any intermediate layer such as a barrier layer or a high-k cap layer (e.g., silicon nitride).

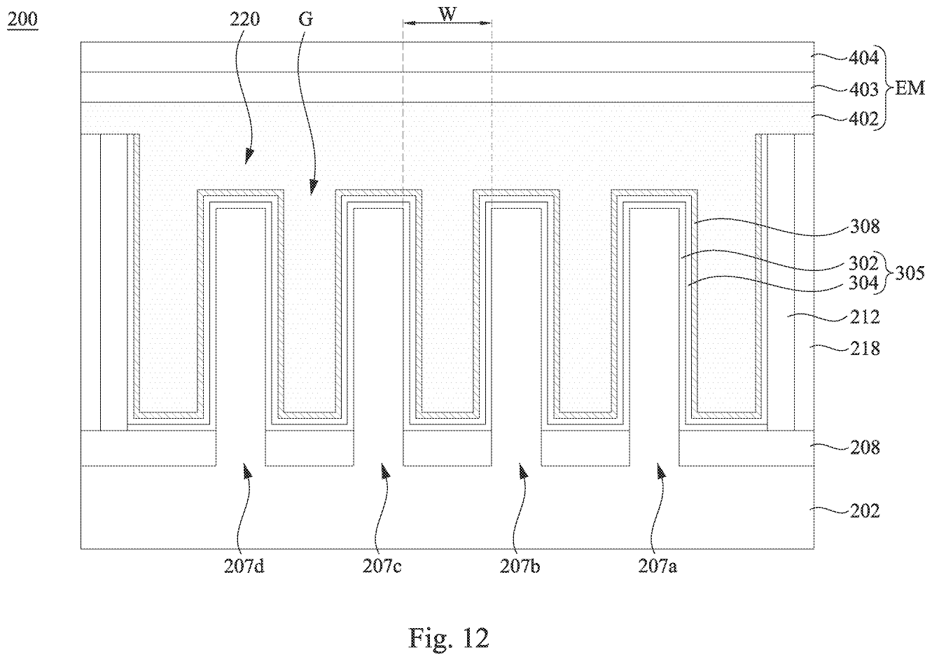

Please refer to FIG. 12. As shown in FIG. 12, an etching mask EM including a protective layer 402 (e.g., bottom antireflective coating), an optional middle layer 403, and a photoresist layer 404 are formed in the gate trench 220 and on the ILD layer 218. The etching mask EM is formed over the substrate 202. It is noted that the substrate 202 has a plurality of protrusions (i.e., fins 207a-207d) and a plurality of gaps G, and the protective layer 402 fills into the gaps G. In some embodiments, gaps G between adjacent fins respectively have a gap width W less than or equal to about 10 nm, about 8 nm, about 6 nm, about 4 nm, or about 2 nm. In some embodiments, after forming or filling the protective layer 402 or the composition used for forming the protective layer 402 in the gaps G, a bake process is performed to enhance the degree of cross-linking of the protective layer 402. In some embodiments, the baking temperature is between 180° C. and 300° C., such as 180, 200, 220, 240, 260, 280, or 300° C. If the baking temperature is greater than 300° C., the polymers may degrade. In some embodiments, the aryl substituted with 1, 2, 3, 4, or 5 hydroxyl groups in the polymer can enhance the adhesion of the protective layer 402 to the p-type WFM layer 308. Further, this aryl also can enhance the adhesion of the protective layer 402 to a n-type WFM layer. In some other embodiments, the etching mask EM can be applied for patterning other components, such as the WFM layer, in a gate-all-around (GAA) FET.

In some embodiments, the protective layer 402 is formed by the composition of any one of embodiments mentioned previously. For example, the composition includes the polymer P2, the polymer P3, the polymer P4, or combinations thereof. In some embodiments, any one of the polymers used for forming the protective layer and any one of the compositions in the previously mentioned embodiments can be used for forming the protective layer 402. Since the protective layer 402 or the composition used for forming the protective layer 402 has high gap-filling ability, the gaps G can be filled with the protective layer 402 without voids. In some embodiments, the optional middle layer 403 includes an inorganic material, such as a nitride (such as silicon nitride), an oxynitride (such as silicon oxynitride), an oxide (such as silicon oxide), or combinations thereof. In some embodiments, the photoresist layer 404 includes an organic material, such as diazonaphthoquinone, novolac resins, bisphenol A novolac epoxy, off-stoichiometry thiol-enes (OSTE) polymer, or combinations thereof. In some embodiments, the protective layer 402 is formed by a spin-on process. In some embodiments, the optional middle layer 403 and the photoresist layer 404 are blanket deposited by using, for example, spin-on process, CVD, ALD, PVD, or combinations thereof.

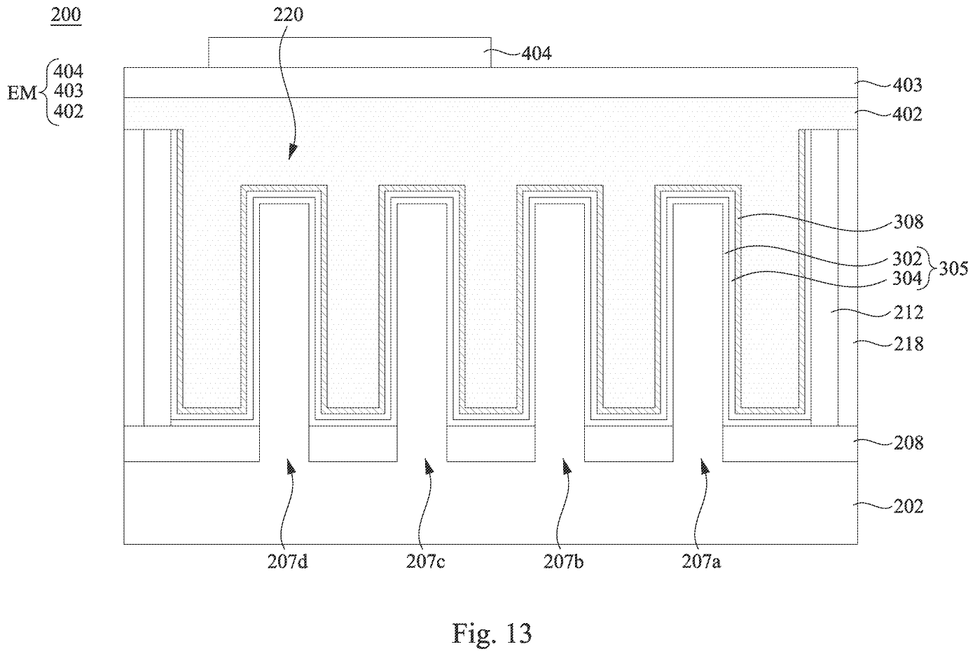

Please refer to FIG. 13. The photoresist layer 404 is patterned to expose the optional middle layer 403 by a photolithographic process including exposing, performing a post-exposure bake process, and developing the photoresist layer 404.

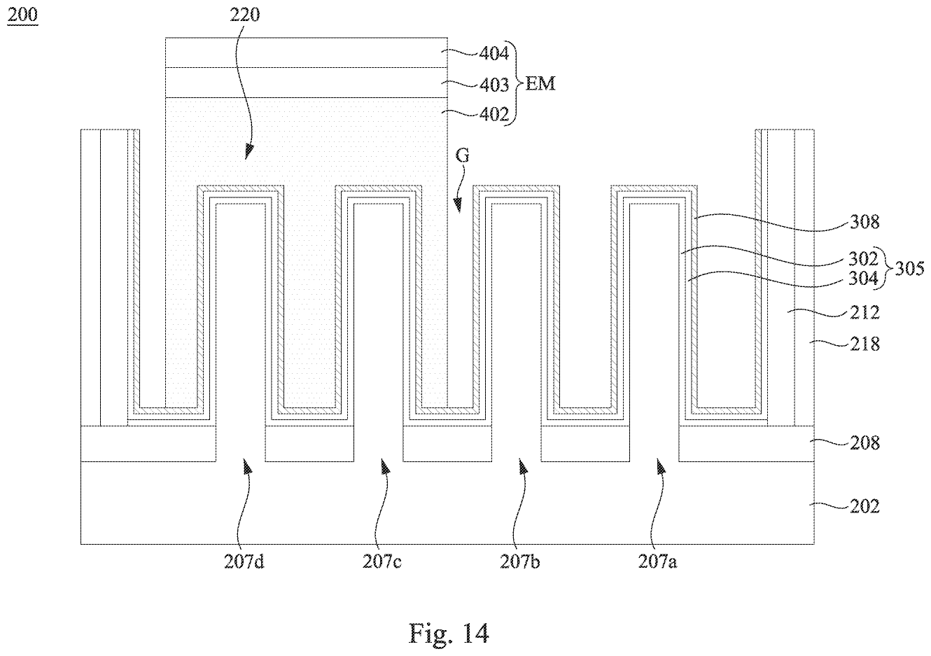

Please refer to FIG. 14. The protective layer 402 and the optional middle layer 403 are patterned by using the photoresist layer 404 as an etching mask. The patterning is performed by a dry etching and/or other suitable processes. For example, the dry etching may utilize a nitrogen-containing etchant gas (e.g., N2), a hydrogen-containing etchant gas (e.g., H2), a fluorine-containing etchant gas (e.g., CF4, SF6, CH2F2. CHF3, and/or C2F6), an oxygen-containing gas, a chlorine-containing gas (e.g., Cl2, CHCI3, CC14, and/or BCl3), a bromine-containing gas (e.g., HBr and/or CHBr3), an iodine-containing gas, helium, and/or other suitable gases and/or plasmas. In an embodiment, the dry etching implements a mixture of N2 and H2 gases.

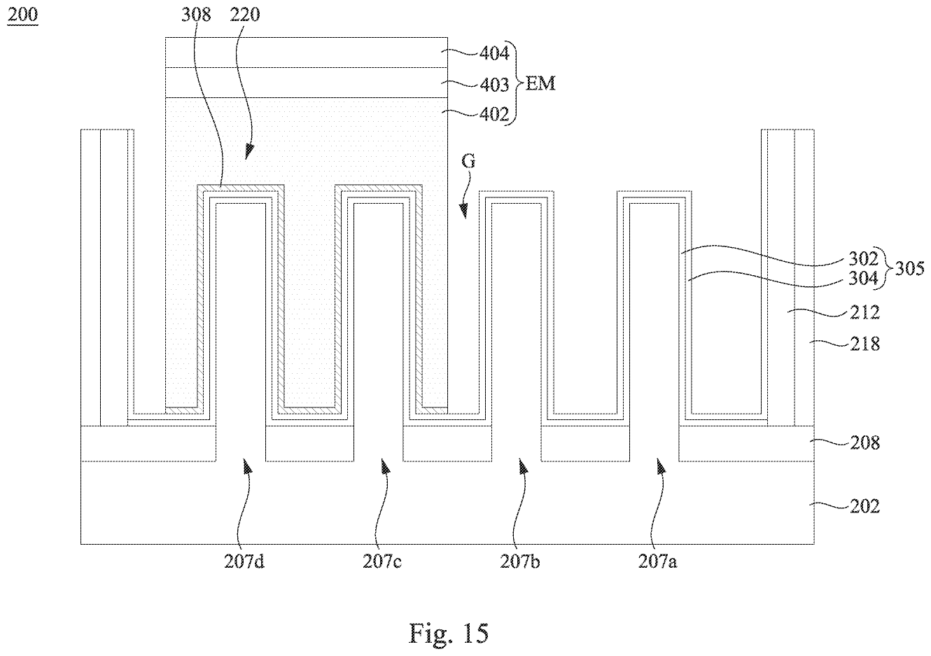

Please refer to FIG. 15. The exposed portions of the p-type WFM layer 308 in the gate trench 220 are removed by using an etch process, thereby exposing the high-k dielectric layer 304 on the fins 207a and 207b. In other words, the p-type WFM layer 308 is patterned by removing the p-type WFM layer 308 over the fins 207a and 207b. thereby leaving the p-type WFM layer 308 over the fin 207c and 207d. Any suitable etch process including dry etching, wet etching, RIE, and/or other suitable processes may be used. A suitable etchant such as standard cleaning solutions SC1 (containing NH₄OH or other alkaline solutions) and SC2 (containing hydrochloric, phosphoric, sulfuric acids or other acidic solutions) may be used to selectively etch the p-type WFM layer 308. Although the p-type WFM layer 308 is in direct contact with the high-k dielectric layer 304, the etch process does not remove or otherwise damage the high-k dielectric layer 304 due to etch selectivity between the p-type WFM layer 308 and the high-k dielectric layer 304. In some embodiments, an etchant removes the p-type WFM layer 308 at an etch rate that is at least 100 times faster than the high-k dielectric layer 304. Such a drastic difference in etch rates ensures that the removal of exposed portions of the p-type WFM layer 308 does not substantively remove or otherwise damage any portion of the high-k dielectric layer 304. Since the protective layer 402 is free of defects, such as voids, the remaining portion of the p-type WFM layer 308 can be protected by the protective layer 402 from being damaged during the etching process, such as wet etching.

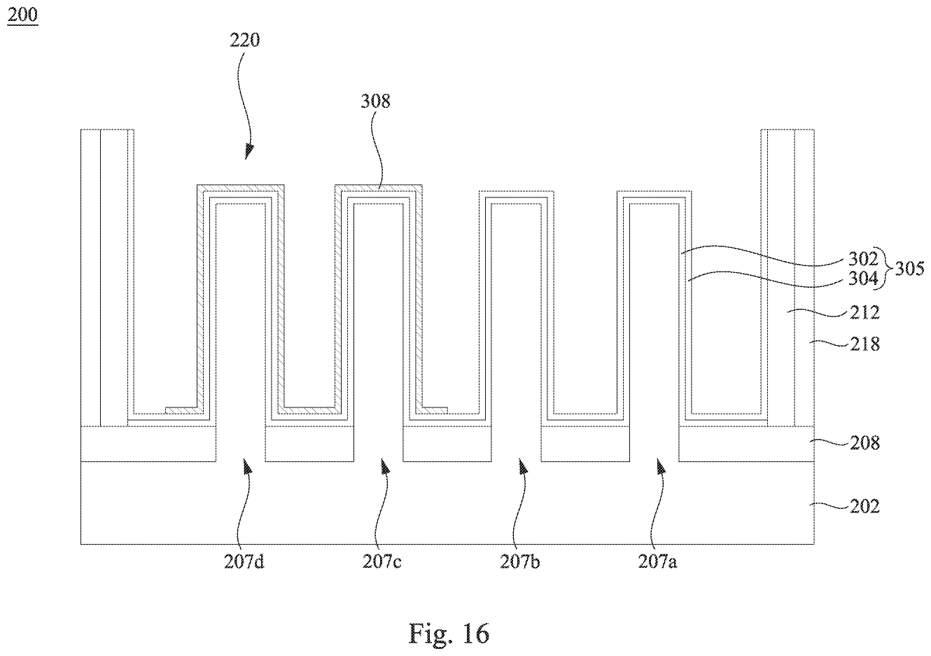

Please refer to FIG. 16. The protective layer 402, the optional middle layer 403, and the photoresist layer 404 are removed by any suitable etch process.

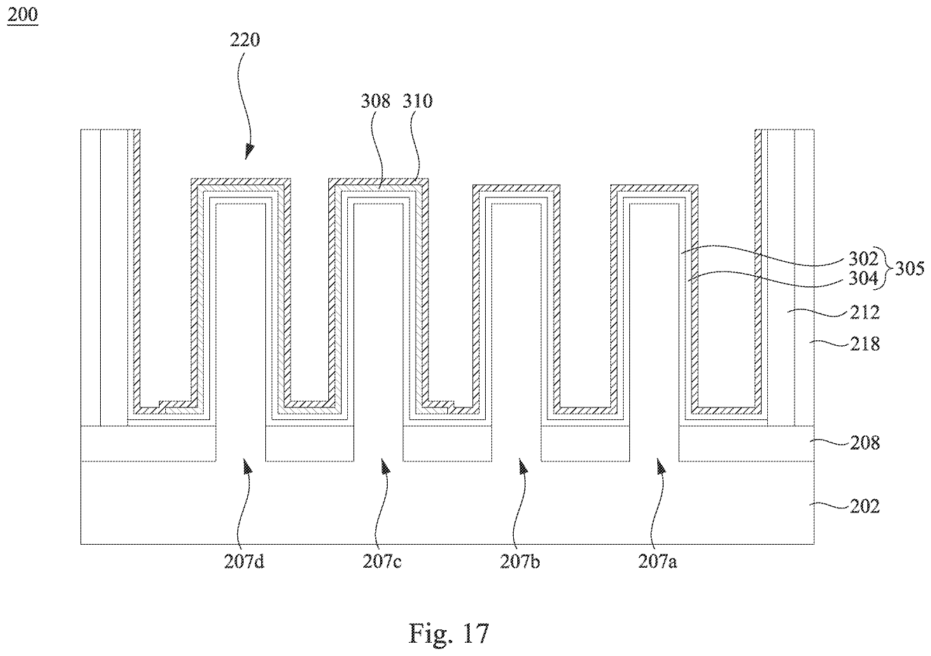

Please refer to FIG. 17. An n-type WFM layer 310 is formed on the patterned p-type WFM layer 308 in the gate trench 220. In some embodiments, the n-type WFM layer 310 is designed (in terms of material and/or thickness) to tune or modulate the threshold voltages of the fins 207a-207d. The n-type WFM layer 310 may include a metal with sufficiently low effective work function, selected from but not restricted to the group of titanium (Ti), aluminum (Al), titanium aluminum (TiAl), titanium aluminum carbide (TiAIC), titanium aluminum nitride (TiAIN), tantalum carbide (TaC), tantalum silicon carbide (TaSiC), tantalum aluminum carbide (TaAIC), tantalum carbide nitride (TaCN), tantalum silicon nitride (TaSiN), titanium silicon nitride (TiSiN), niobium aluminum carbide (NbAIC), hafnium carbide (HfC), or combinations thereof. The n-type WFM layer 310 may be formed by a deposition process such as ALD, CVD, PVD, and/or other suitable processes. Depending on the desired work functions on the fins 207a-207d, the n-type WFM layer 310 may be formed to a suitable thickness (e.g., about 2 nm to about 3 nm).

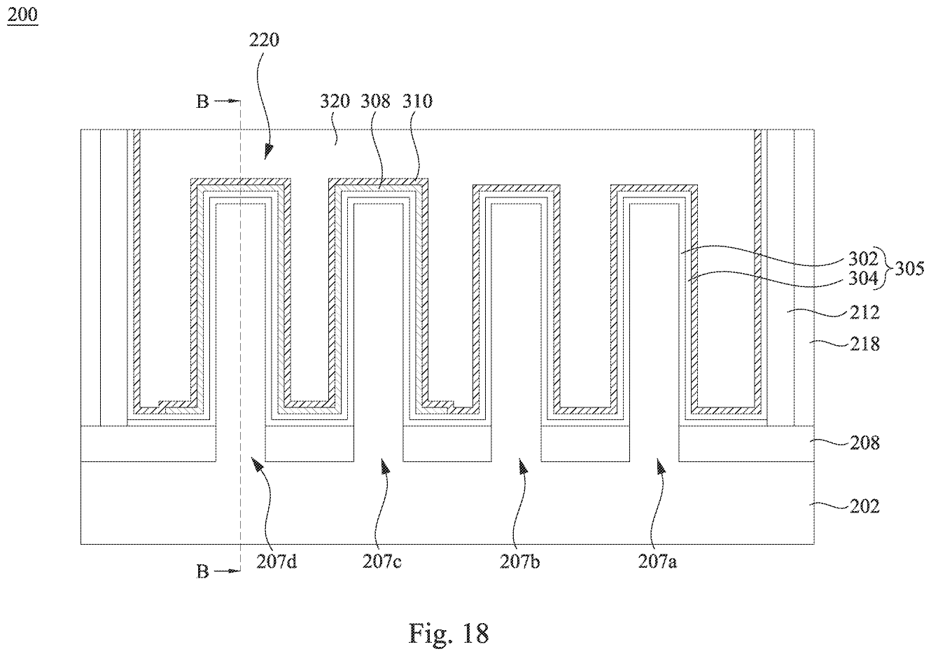

Please refer to FIG. 18. A fill metal layer 320 is formed in the remaining space of the gate trench 220 to complete a metal gate structure. The fill metal layer 320 is disposed over and in direct contact with the n-type WFM layer 310. The fill metal layer 320 may include copper (Cu), tungsten (W), aluminum (Al), cobalt (Co), and/or other suitable materials. The fill metal layer 320 may be formed by ALD, CVD, PVD, plating, and/or other suitable processes. A CMP process may be performed to remove excess materials to planarize a top surface of the semiconductor device 200. After formation of the fill metal layer 320, the gate structure is complete. The gate structure (including the interfacial layer 302, the high-k dielectric layer 304, the p-type WFM layer 308, the n-type WFM layer 310, and the fill metal layer 320) is formed over and surrounds a channel, which sits between a source and a drain on each fin. Thus, each fin is part of a FinFET, which includes a source, a drain, a channel, and a gate. When multiple sources, drains, and channels are implemented onto a fin, the fin may be considered part of multiple FinFETs.

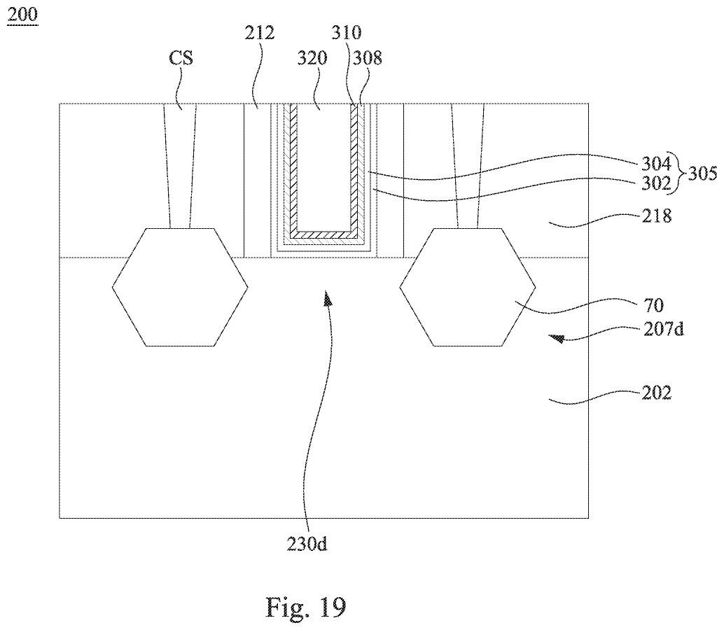

FIG. 19 is a cross-sectional view along a line B-B of FIG. 18 in accordance with some embodiments. The interfacial layer 302, the high-k dielectric layer 304, the p-type WFM layer 308, the n-type WFM layer 310, and the fill metal layer 320 are filled in the gate trench 220. The interfacial layer 302 covers the sidewalls of the gate spacers 212 and a bottom of the gate trench 220. The high-k dielectric layer 304 covers the interfacial layer 302. The p-type WFM layer 308 covers the high-k dielectric layer 304. The n-type WFM layer 310 covers the p-type WFM layer 308. The fill metal layer 320 is disposed on the n-type WFM layer 310. The source/drain regions 70 are formed in the fin 207d and are separated by the channel region 230d. In some embodiments, the source/drain regions 70 are formed by an epitaxial growth method. The source/drain regions 70 are epitaxial layers. The source/drain regions 70 may include one or more layers of Si, SiP, SiC, and SiCP for an n-channel FET or Si, SiGe, or Ge for a p-channel FET. Contact structures CS are disposed in the ILD layer 218 to electrically connect with the source/drain regions 70. In some embodiments, the source/drain regions 70 include conductive materials, such as cobalt (Co), tungsten (W), ruthenium (Ru), iridium (Ir), nickel (Ni), osmium (Os), rhodium (Rh), aluminum (Al), molybdenum (Mo), other suitable conductive materials, or combinations thereof. In some other embodiments, the p-type WFM layer 308 is replaced with a n-type WFM layer, and the n-type WFM layer 310 is replaced with a p-type WFM layer.

Based on the above discussions, it can be seen that the present disclosure offers the composition used for forming the protective layer (e.g., BARC) and the method of manufacturing the semiconductor device by using the protective layer. Since the compositions have high gap-filling ability, high wet etch resistance, and good adhesion ability to the metal layer (e.g., p-type WFM layer, n-type WFM layer), in the semiconductor device, the metal layer covering the substrate having the protrusions and gaps can be protected by the protective layer without being damaged during the etching process. Therefore, the semiconductor device can have good electrical performance.

In some embodiments, a method of manufacturing a semiconductor device includes the following operations. A protective layer is formed over a substrate, in which the protective layer is formed by a composition including a polymer having a polymer backbone and end groups. The polymer backbone is formed by polymerizing a monomer composition including first monomers, and each of the first monomer independently has an aryl substituted with 1, 2, 3, 4, or 5 hydroxyl groups. The end groups include:

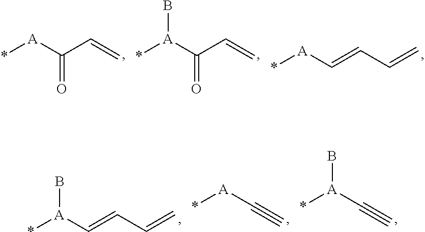

or combinations thereof. A is a substituted or unsubstituted hydrocarbon group. B is a hydroxyl group, an alkyl group, or a fluoroalkyl group. A photoresist layer is formed over the protective layer. The photoresist layer is patterned.

In some embodiments, a method of manufacturing a semiconductor device includes the following operations. A bottom anti-reflective coating is formed over a substrate, in which the bottom anti-reflective coating is formed by a composition including a first polymer having a first polymer backbone. The first polymer backbone is substituted with one or more functional groups including:

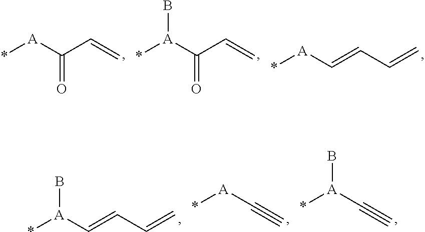

or combinations thereof. A is a substituted or unsubstituted hydrocarbon group. B is a hydroxyl group, an alkyl group, or a fluoroalkyl group. A photoresist layer is formed over the bottom anti-reflective coating. The photoresist layer is patterned.

In some embodiments, a composition includes a polymer, a cross-linker, and a solvent. The polymer has a polymer backbone and first end units, in which the polymer backbone and the first end units are independently unsubstituted or substituted with one or more functional groups including

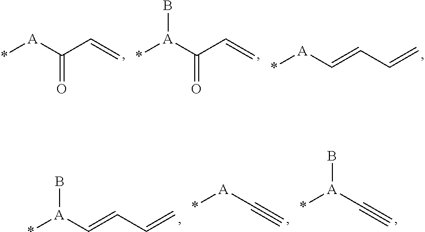

or combinations thereof. A is a substituted or unsubstituted hydrocarbon group. B is a hydroxyl group, an alkyl group, or a fluoroalkyl group. The polymer backbone, the first end units, or a combination thereof is substituted.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a protective layer over a substrate, wherein the protective layer is formed by a composition comprising a polymer having a polymer backbone and end groups, the polymer backbone is formed by polymerizing a monomer composition comprising first monomers, each of the first monomer independently has an aryl substituted with 1, 2, 3, 4, or 5 hydroxyl groups, the end groups comprise: 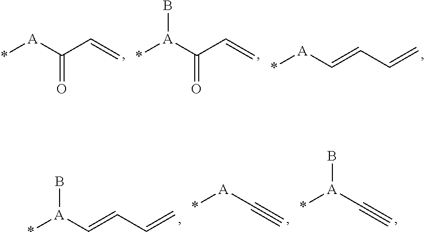
or combinations thereof, A is a substituted or unsubstituted hydrocarbon group, and B is a hydroxyl group, an alkyl group, or a fluoroalkyl group;
forming a photoresist layer over the protective layer; and
patterning the photoresist layer.

2. The method of claim 1, wherein 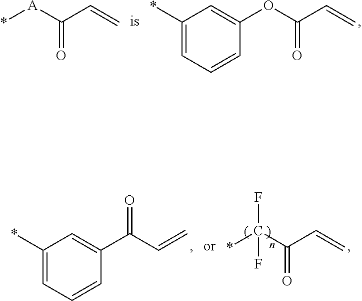
and n is 1-2.

3. The method of claim 1, wherein

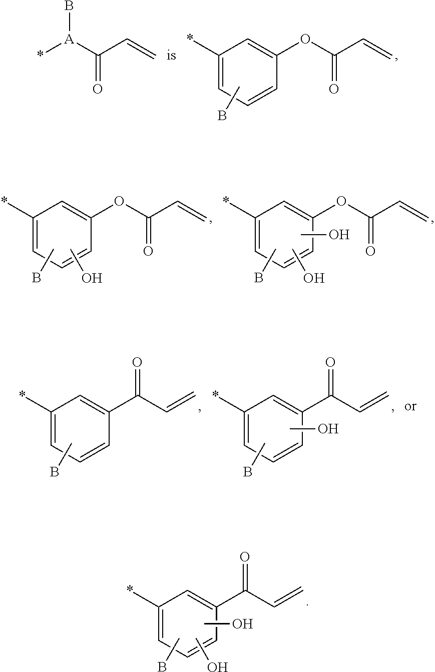

4. The method of claim 1, wherein 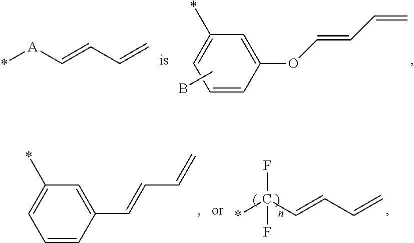
and n is 1-2.

5. The method of claim 1, wherein

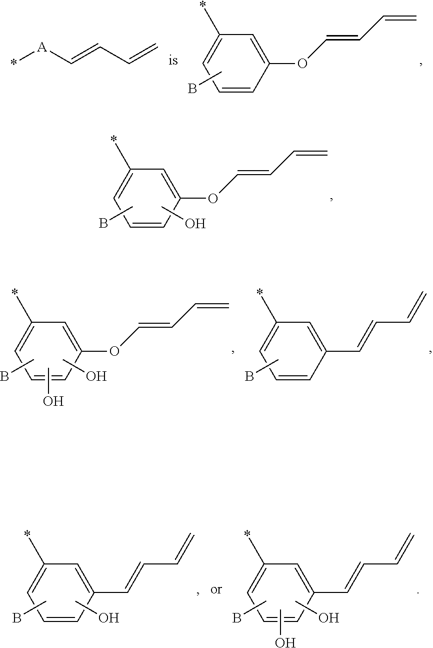

6. The method of claim 1, wherein 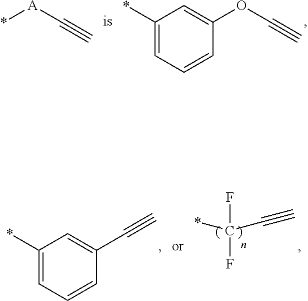
and n is 1-2.

7. The method of claim 1, wherein

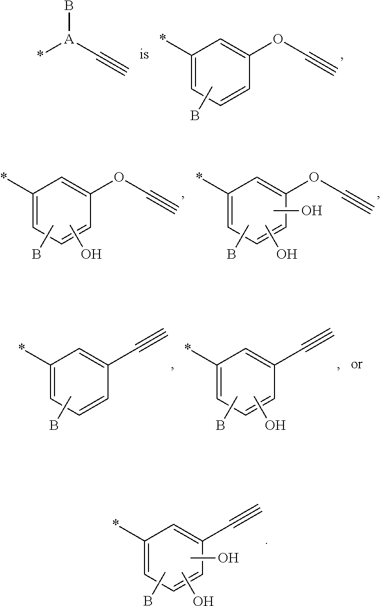

8. The method of claim 1, wherein the polymer comprises a novolac polymer, a substituted poly(hydroxystyrene), an unsubstituted poly(hydroxystyrene), an acrylate polymer, a substituted polyethylene, or combinations thereof, and the substituted poly(hydroxystyrene) and the substituted polyethylene are respectively substituted with a hydroxyphenyl, a di-hydroxyphenyl, a tri-hydroxyphenyl, a tetra-hydroxyphenyl, a penta-hydroxyphenyl, or combinations thereof.

9. The method of claim 1, wherein the polymer backbone has repeating units comprising 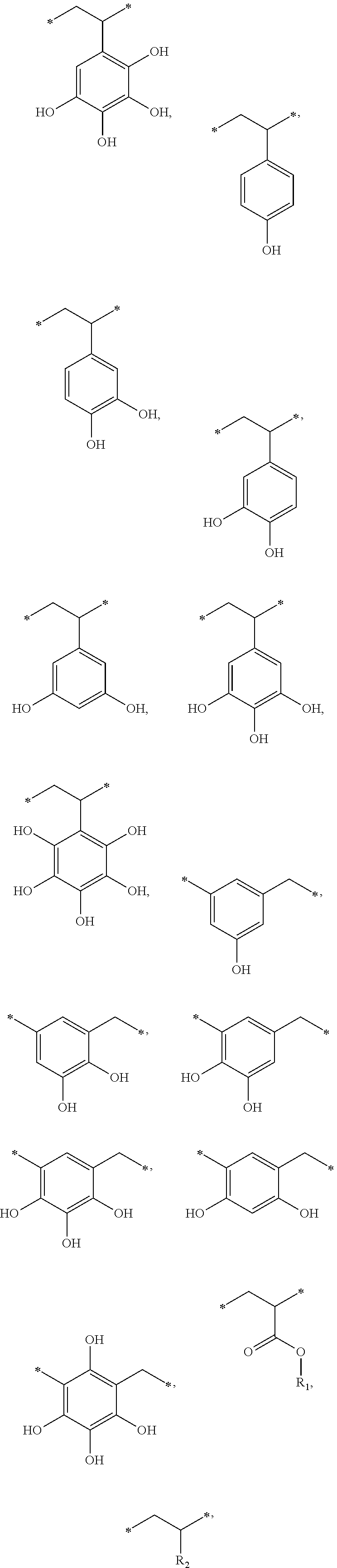
or combinations thereof, and R₁ and R₂ are independently a hydroxyphenyl, a di-hydroxyphenyl, a tri-hydroxyphenyl, a tetra-hydroxyphenyl, or a penta-hydroxyphenyl.

10. The method of claim 1, wherein the monomer composition further comprises second monomers, each of the second monomer independently has an aryl substituted with 1, 2, 3, 4, or 5 hydroxyl groups, the second monomers are respectively substituted with a functional group comprising 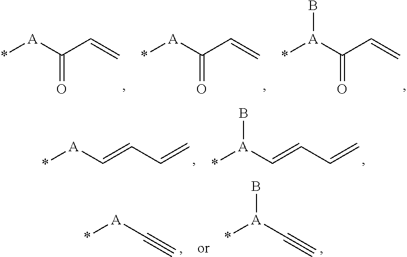
A is a substituted or unsubstituted hydrocarbon group, and B is a hydroxyl group, an alkyl group, or a fluoroalkyl group.

11. The method of claim 1, further comprising:
forming a work function metal layer substantially conformally covering the substrate before forming the protective layer over the substrate, wherein the substrate has a plurality of protrusions and a plurality of gaps.

12. A method of manufacturing a semiconductor device, comprising:
forming a bottom anti-reflective coating over a substrate, wherein the bottom anti-reflective coating is formed by a composition comprising a first polymer having a first polymer backbone, the first polymer backbone is substituted with one or more functional groups comprising: 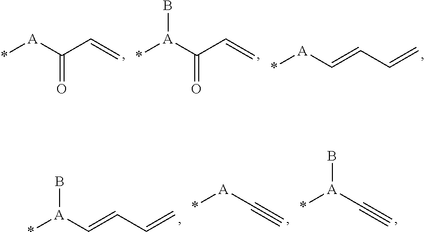
or combinations thereof, A is a substituted or unsubstituted hydrocarbon group, and B is a hydroxyl group, an alkyl group, or a fluoroalkyl group;
forming a photoresist layer over the bottom anti-reflective coating; and
patterning the photoresist layer.

13. The method of claim 12, wherein the first polymer backbone has repeating units comprising: 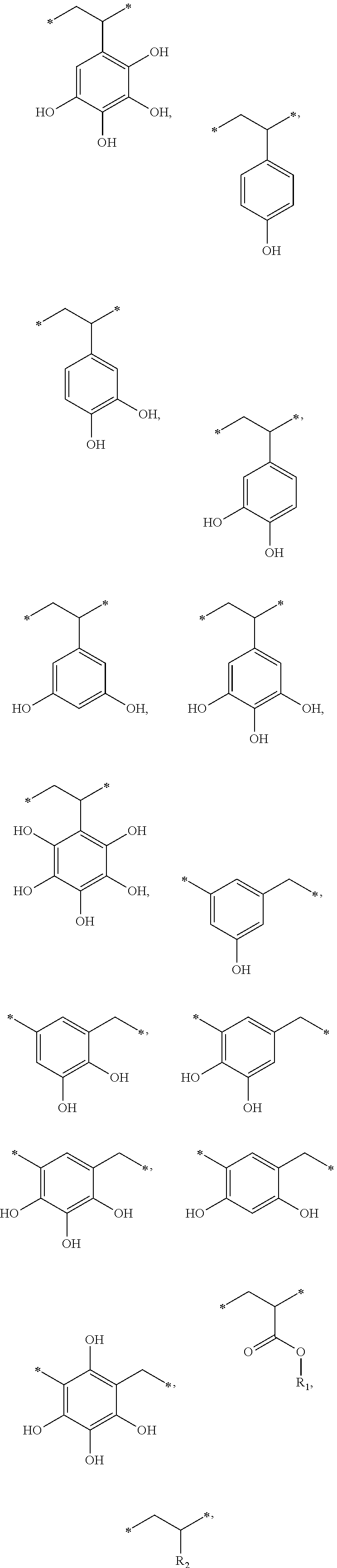
or combinations thereof, R₁ and R₂ are independently a hydroxyphenyl, a di-hydroxyphenyl, a tri-hydroxyphenyl, a tetra-hydroxyphenyl, or a penta-hydroxyphenyl, and the repeating units are substituted with the functional group.

14. The method of claim 12, wherein the composition further comprises a second polymer having a second polymer backbone and end groups, the end groups comprise: 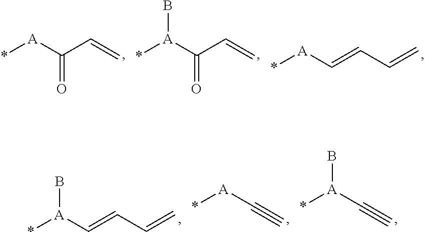
or combinations thereof, A is a substituted or unsubstituted hydrocarbon group, and B is a hydroxyl group, an alkyl group, or a fluoroalkyl group.

15. The method of claim 12, wherein the composition further comprises one or more additives comprising: 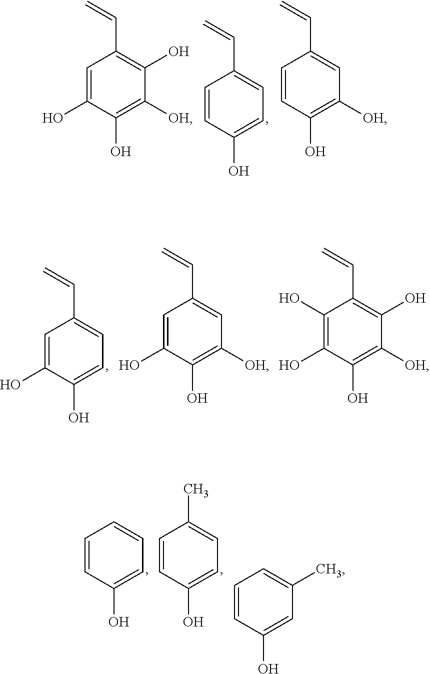
benzene-1,2-diol, benzene-1,3-diol, benzene-1,4-diol, benzene-1,2,3-triol, benzene-1,2,4-triol, benzene-1,3,5-triol, 1,2,3,4-tetrahydroxybenzene, 1,2,3,5-tetrahydroxybenzene, 1,2,4,5-tetrahydroxybenzene, 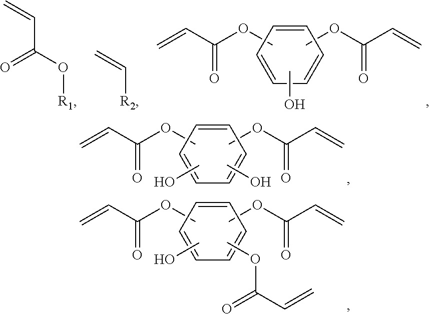
or combinations thereof, R₁ and R₂ are independently a hydroxyphenyl, a di-hydroxyphenyl, a tri-hydroxyphenyl, a tetra-hydroxyphenyl, or a penta-hydroxyphenyl, and the additives are respectively substituted with one or more functional groups comprising: 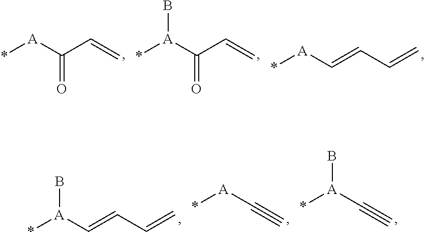
or combinations thereof, A is a substituted or unsubstituted hydrocarbon group, and B is a hydroxyl group, an alkyl group, or a fluoroalkyl group.

16. The method of claim 12, wherein the substrate has a plurality of protrusions and a plurality of gaps, and the bottom anti-reflective coating fills into the gaps when forming the bottom anti-reflective coating over the substrate.

17. The method of claim 16, wherein the gaps respectively have a gap width less than or equal to about 10 nm.

18. A composition, comprising:
a polymer having a polymer backbone and first end units, wherein the polymer backbone and the first end units are independently unsubstituted or substituted with one or more functional groups comprising 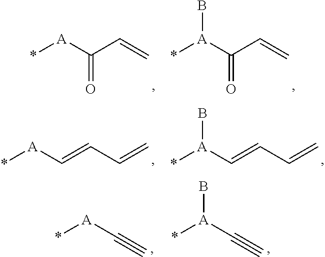
or combinations thereof, A is a substituted or unsubstituted hydrocarbon group, B is a hydroxyl group, an alkyl group, or a fluoroalkyl group, and the polymer backbone, the first end units, or a combination thereof is substituted;
a cross-linker; and
a solvent.

19. The composition of claim 18, wherein the polymer has a weight-average molecular weight between greater than 1000 daltons and 10000 daltons.

20. The composition of claim 18, further comprising an oligomer having an oligomer backbone and second end units and having a weight-average molecular weight between 500 daltons and 1000 daltons, wherein the oligomer backbone and the second end units are independently unsubstituted or substituted with one or more functional groups comprising 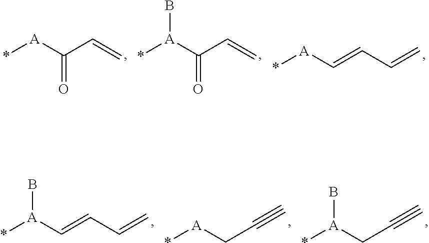
or combinations thereof, A is a substituted or unsubstituted hydrocarbon group, B is a hydroxyl group, an alkyl group, or a fluoroalkyl group, and the oligomer backbone, the second end units, or a combination thereof is substituted.
